(19) United States
(12) Patent Application Publication
(10) Pub. No.: US 2006/0065894 A1
(43) Pub. Date: Mar. 30, 2006

(54) Thin film transistor array panel and manufacturing method thereof

(76) Inventors: Jin-Goo Jung, Seoul (KR); Chun-Gi You, Yongin-si (KR); Kyung-Min Park, Seongnam-si (KR)

Correspondence Address: CANTOR COLBURN, LLP, 55 GRIFFIN ROAD SOUTH, BLOOMFIELD, CT, 06002, US

(21) Appl. No.: 11/232,736

(22) Filed: Sep. 22, 2005

(30) Foreign Application Priority Data
Sep. 24, 2004 (KR) 10 -2004-0077069
Sep. 24, 2004 (KR) 10-2004-0077070

(51) Int. Cl. H01L 29/786; H01L 21/84

(52) U.S. Cl. 257/66; 438/151; 438/163; 257/72

(57) ABSTRACT

A thin film transistor array panel is provided, which includes a substrate having a display area and driver, a polysilicon layer formed on the substrate and including channel, source, and drain regions, and lightly doped regions disposed between the channel region and the source and drain regions, and having an impurity concentration lower than the source and the drain regions, a gate insulating layer formed on the polysilicon layer, an impurity layer formed on the gate insulating layer and overlapping the channel region of the polysilicon layer and doped with impurities, a gate electrode formed on the impurity layer, an interlayer insulating layer covering the gate electrode and having first and second contact holes respectively exposing the source and drain regions, and source and drain electrodes respectively connected to the source and drain regions via the first and the second contact holes.

This application claims priority to Korean Patent Application No. 10-2004-0077069, filed on Sep. 24, 2004, and to Korean Patent Application No. 10-2004-0077070, filed on Sep. 24, 2004 and all the benefits accruing therefrom under 35 U.S.C. §119, and the contents of which in their entirety are herein incorporated by reference.

### BACKGROUND OF THE INVENTION

(a) Field of the Invention

The present invention relates to a thin film transistor (“TFT”) array panel and a manufacturing method thereof. More particularly, the present invention relates to a TFT array panel with increased reliability and a manufacturing method thereof.

(b) Description of the Related Art

A flat panel display such as a liquid crystal display (“LCD”) and an organic light emitting display (“OLED”) includes a display panel including a plurality of pixel electrodes, a plurality of thin film transistors (“TFTs”) connected thereto, a plurality of signal lines connected to the TFTs, a plurality of drivers for driving the display panel, and a controller for controlling the drivers.

The signal lines include gate lines for transmitting gate signals from the drivers to the TFTs, and data lines for transmitting data signals from the drivers to the TFTs.

A TFT includes a semiconductor layer of amorphous silicon a-Si or polysilicon, gate electrodes connected to the gate lines, source electrodes connected to the data lines, and drain electrodes connected to the pixel electrodes.

A polysilicon TFT using polysilicon for a semiconductor layer has relatively higher electron mobility than does an amorphous silicon a-Si TFT, and the polysilicon TFT enables implementation of a chip in glass technique in which a display panel embeds its driving circuits therein.

A TFT including a polysilicon layer usually places the gate electrode on the polysilicon layer, and the polysilicon layer includes lightly doped drain (“LDD”) regions disposed between a channel region and source and drain regions for reducing punch-through, etc. A TFT having a structure with lightly doped drain regions overlapping the gate electrodes is widely used because of its high reliability.

However, current leakage and parasitic capacitance between the gate electrode and the semiconductor layer are increased, thereby generating distortion of signals.

Heavily doped regions such as source and drain regions and the lightly doped regions are often formed by making a gate electrode from two metal films having different widths and by using the two metal films as masks for forming the two regions.

However, it is difficult to differentiate the two metal films using only one lithography step and to define the length of the lightly doped regions and therefore the process time is long and productivity is decreased.

### BRIEF SUMMARY OF THE INVENTION

In an exemplary embodiment of the present invention, a thin film transistor array panel is provided, which includes a substrate having a display area and a driver, a polysilicon layer formed on the substrate, the polysilicon layer including a channel region, source and drain regions, and lightly doped regions disposed between the channel region and the source and drain regions, the lightly doped regions having an impurity concentration lower than an impurity concentration of the source and the drain regions, a gate insulating layer formed on the polysilicon layer, an impurity layer formed on the gate insulating layer and overlapping the channel region of the polysilicon layer, the impurity layer doped with impurities, a gate electrode formed on the impurity layer, an interlayer insulating layer covering the gate electrode and having first and second contact holes respectively exposing the source and the drain regions, and source and drain electrodes respectively connected to the source and the drain regions via the first and the second contact holes.

The polysilicon layer may be disposed in the display area, and the panel may further include a gate line connected to the gate electrode, a data line connected to the source electrode and crossing over the gate line, and a pixel electrode connected to the drain electrode, and may further include a passivation layer disposed between the pixel electrode and the drain electrode.

The polysilicon layer may be disposed in the driver.

The polysilicon layer may include first and second polysilicon layers respectively disposed in the display area and the driver and respectively doped with first and second conductivity impurities, and the impurity layer may include first and second impurity layers doped with the first conductivity impurities and respectively disposed on the first and the second polysilicon layers. The first conductivity impurities may be N-type impurities, and the second conductivity impurities may be P-type impurities.

The lightly doped regions are respectively disposed in the first and the second polysilicon layers and are respectively doped with the first and second conductivity impurities.

The lightly doped regions may be only disposed in the first polysilicon layer.

The impurity layer may overlap the lightly doped regions, and may not overlap the source and drain regions.

The impurity layer and the gate insulating layer may have a substantially same planar shape, such that the gate insulating layer overlaps the channel region but does not overlap the source and drain regions.

The polysilicon layer may further include a storage region spaced from the channel region by the drain region, the impurity layer further including a first impurity layer overlapping the channel region and a second impurity layer overlapping the storage region.

In another exemplary embodiment of the present invention, a method of manufacturing a thin film transistor array panel is provided, which includes forming a polysilicon layer on a substrate, depositing a gate insulating layer on the substrate, depositing a doped silicon layer on the gate insulating layer, depositing a conductive film on the doped silicon layer, forming a photoresist relative to the conductive film, patterning the conductive film by isotropic etching using the photoresist as an etch mask to form a gate electrode, patterning the doped silicon layer by anisotropic etching using the photoresist as an etch mask to form an impurity layer, forming source and drain regions having a first impurity concentration by introducing impurities into the polysilicon layer using the impurity layer as a mask, forming lightly doped regions having a second impurity concentration lower than the first impurity concentration by introducing impurities into the polysilicon member using the gate electrode as a mask, forming an interlayer insulating layer covering the gate electrode having contact holes respectively exposing the source and the drain regions, and forming source and drain electrodes on the interlayer insulating layer, the source and drain electrodes respectively connected to the source and the drain regions via the contact holes.

The method may further include forming a pixel electrode connected to the drain electrode.

The introduction of the impurities for the formation of the source and drain regions may be performed by plasma enhanced chemical vapor deposition or plasma emulsion.

The gate insulating layer may be etched when patterning the doped silicon layer.

In another exemplary embodiment of the present invention, a thin film transistor array panel is provided that includes an insulating layer, a gate conductor transmitting gate signals, and an impurity layer doped with impurities and interposed between the insulating layer and the gate conductor.

The semiconductor layer may include a source region, a drain region, and a channel region disposed between the source region and the drain region such that the insulating layer is disposed on the semiconductor layer, and the impurity layer overlaps the channel region and does not overlap the source and drain regions.

A first lightly doped region may be provided between the source region and the channel region and a second lightly doped region may be provided between the channel region and the drain region, such that the impurity layer overlaps the first and second lightly doped regions.

The impurity layer may be doped with N-type conductive impurities.

### BRIEF DESCRIPTION OF THE DRAWINGS

The present invention will become more apparent by describing embodiments thereof in detail with reference to the accompanying drawings, in which:

FIG. 1 is a block diagram of an exemplary embodiment of an LCD according to the present invention;

FIG. 2 is an equivalent circuit diagram of an exemplary embodiment of a pixel of an LCD according to the present invention;

FIG. 3 is a layout view of an exemplary embodiment of the TFT array panel shown in FIGS. 1 and 2 according to the present invention;

FIG. 4 is a sectional view of the display area shown in FIG. 3 taken along line IV-IV′;

FIG. 5 is a sectional view of a TFT of the driver shown in FIGS. 1 and 2;

FIG. 6 is a layout view of the TFT array panel shown in FIGS. 3 and 4 in a first step of an exemplary embodiment of a manufacturing method thereof according to the present invention;

FIG. 7 is a sectional view of the TFT array panel shown in FIG. 6 taken along line VII-VII′;

FIG. 8 is a sectional view of the TFT of the driver shown in FIG. 5 in the step shown in FIGS. 6 and 7;

FIG. 9 is a sectional view of the TFT array panel shown in FIG. 6 taken along line VII-VII′, and illustrates the step following the step shown in FIGS. 7 and 8;

FIG. 10 is a sectional view of the TFT of the driver in the step shown in FIG. 9;

FIG. 11 is a layout view of the TFT array panel in the step following the step shown in FIGS. 9 and 10;

FIG. 12 is a sectional view of the TFT array panel shown in FIG. 11 taken along line XII-XII′;

FIG. 13 is a sectional view of the TFT of the driver in the step shown in FIGS. 11 and 12;

FIG. 14 is a layout view of the TFT array panel in the step following the step shown in FIGS. 11 to 13;

FIG. 15 is a sectional view of the TFT array panel shown in FIG. 14 taken along line XV-XV′;

FIG. 16 is a sectional view of the TFT of the driver in the step shown in FIGS. 14 and 15;

FIG. 17 is a sectional view of the TFT array panel shown in FIG. 14 taken along line XV-XV′, and illustrates the step following the step shown in FIGS. 14 to 16;

FIG. 18 is a sectional view of the TFT of the driver in the step shown in FIG. 17;

FIG. 19 is a sectional view of the TFT array panel shown in FIG. 14 taken along line XV-XV′, and illustrates the step following the step shown in FIGS. 17 and 18;

FIG. 20 is a sectional view of the TFT of the driver in the step shown in FIG. 19;

FIG. 21 is a sectional view of the TFT of the driver in the step following the step shown in FIG. 20;

FIG. 22 is a sectional view of the TFT of the driver according to another embodiment in the step following the step shown in FIG. 20;

FIG. 23 is a layout view of the TFT array panel in the step following the step shown in FIG. 20;

FIG. 24 is a sectional view of the TFT array panel shown in FIG. 23 taken along line XXIV-XXIV′;

FIG. 25 is a sectional view of the TFT of the driver in the step shown in FIGS. 23 and 24;

FIG. 26 is a layout view of the TFT array panel in the step following the step shown in FIGS. 22 to 24;

FIG. 27 is a sectional view of the TFT array panel shown in FIG. 26 taken along line XXVII-XXVII′;

FIG. 28 is a sectional view of the TFT of the driver in the step shown in FIGS. 26 and 27;

FIG. 29 is a layout view of the TFT array panel in the step following the step shown in FIGS. 26 to 28;

FIG. 30 is a sectional view of the TFT array panel shown in FIG. 29 taken along the line XXX-XXX′;

FIG. 31 is a sectional view of the TFT of the driver in the step shown in FIGS. 29 and 30;

FIG. 32 is a layout view of another exemplary embodiment of a display area of the TFT array panel shown in FIGS. 1 and 2 according to the present invention;

FIG. 33 is a sectional view of the display area shown in FIG. 32 taken along line XXXIII-XXXIII′;

FIG. 34 is a sectional view of a TFT of the driver shown in FIGS. 1 and 2 for the display area of the TFT array panel of FIGS. 32 and 33;

FIG. 35 is a layout view of the TFT array panel in the intermediate step of another exemplary embodiment of a manufacturing method thereof according to the present invention;

FIG. 36 is a sectional view of the TFT array panel shown in FIG. 35 taken along line XXXVI-XXXVI′;

FIG. 37 is a sectional view of the TFT of the driver in the step shown in FIGS. 35 and 36;

FIG. 38 is a sectional view of the TFT of the driver in the intermediate step of another exemplary embodiment of a manufacturing method thereof according to the present invention; and

FIG. 39 is a sectional view of the TFT of the driver in the intermediate step of another exemplary embodiment of a manufacturing method thereof according to the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as limited to the embodiments set forth herein. Like numerals refer to like elements throughout.

In the drawings, the thickness of layers and regions are exaggerated for clarity. Like numerals refer to like elements throughout. It will be understood that when an element such as a layer, region, or substrate is referred to as being “on” another element, it can be directly on the other element or intervening elements may also be present. In contrast, when an element is referred to as being “directly on” another element, there are no intervening elements present.

Liquid crystal displays (“LCDs”) as exemplary embodiments of display devices according to the present invention will now be described with reference to the accompanying drawings.

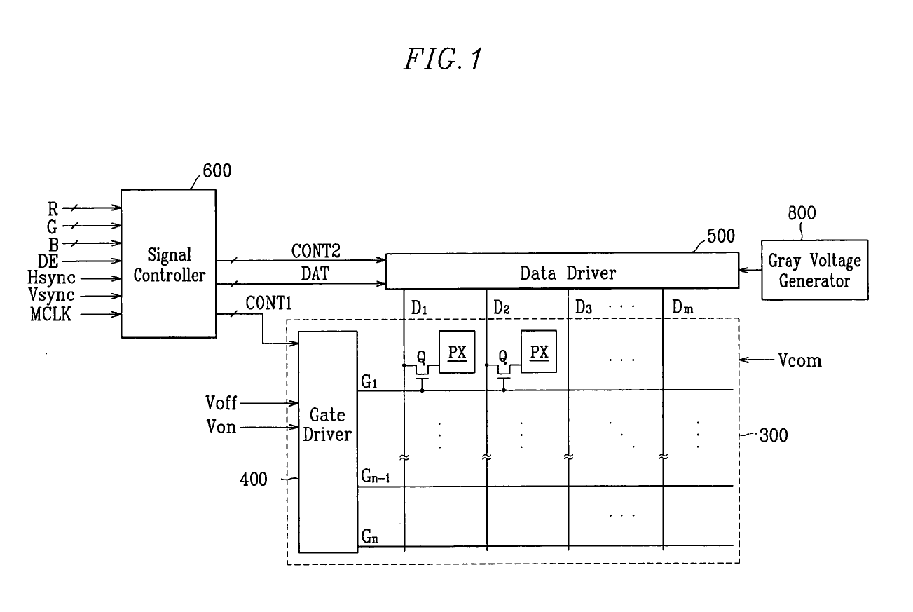

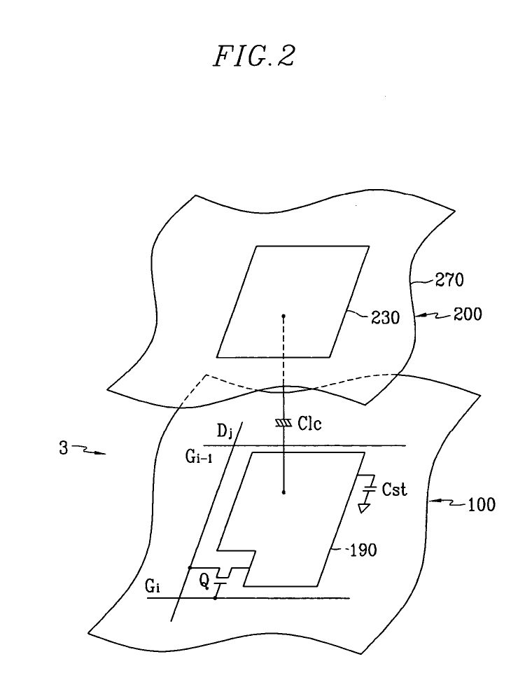

Referring to FIGS. 1 and 2, an exemplary embodiment of an LCD according to the present invention will be described in detail.

FIG. 1 is a block diagram of an exemplary embodiment of an LCD according to the present invention, and FIG. 2 is an equivalent circuit diagram of an exemplary embodiment of a pixel of an LCD according to the present invention.

Referring to FIG. 1, an LCD includes an LC panel assembly 300, a gate driver 400 and a data driver 500 that are connected to the LC panel assembly 300, a gray voltage generator 800 connected to the data driver 500, and a signal controller 600 controlling the above elements.

Referring to FIG. 1, the LC panel assembly 300 includes a plurality of display signal lines G₁-Gₙ and D₁-Dₘ and a plurality of pixels connected thereto and arranged substantially in a matrix. In a structural view shown in FIG. 2, the LC panel assembly 300 includes a lower panel 100 as a thin film transistor (“TFT”) panel and an upper panel 200 as a color filter panel, where the panels 100 and 200 face each other, and an LC layer 3 interposed therebetween.

The display signal lines G₁-Gₙ and D₁-Dₘ are disposed on the lower panel 100 and include a plurality of gate lines G₁-Gₙ transmitting gate signals (also referred to as “scanning signals”) and a plurality of data lines D₁-Dₘ transmitting data signals. The gate lines G₁-Gₙ extend substantially in a row direction and substantially parallel to each other, while the data lines D₁-Dₘ extend substantially in a column direction and substantially parallel to each other.

Each pixel includes a switching element Q connected to the signal lines G₁-Gₙ and D₁-Dₘ, and a LC capacitor Clc and a storage capacitor Cst that are connected to the switching element Q. In an alternative embodiment, the storage capacitor Cst may be omitted if it is unnecessary.

The switching element Q, including a TFT, is provided on the lower panel 100, and has three terminals including a control terminal connected to one of the gate lines G₁-Gₙ, an input terminal connected to one of the data lines D₁-Dₘ, and an output terminal connected to both the LC capacitor Clc and the storage capacitor Cst.

The LC capacitor Clc includes a pixel electrode 190, provided on the lower panel 100, and a common electrode 270, provided on an upper panel 200, as two terminals. The LC layer 3, disposed between the two electrodes 190 and 270, functions as a dielectric of the LC capacitor Clc. The pixel electrode 190 is connected to the switching element Q, and the common electrode 270 is supplied with a common voltage Vcom and covers an entire surface, or substantially the entire surface, of the upper panel 200. Alternatively, both the pixel electrode and the common electrode 270 may be provided on the lower panel 100, and at least one or both electrodes 190 and 270 may have shapes of bars or stripes.

The storage capacitor Cst is an auxiliary capacitor for the LC capacitor Clc. The storage capacitor Cst includes the pixel electrode 190, and a separate signal line that is provided on the lower panel 100, overlaps the pixel electrode 190 via an insulator. The separate signal line is supplied with a predetermined voltage such as the common voltage Vcom. Alternatively, the storage capacitor Cst includes the pixel electrode 190 and an adjacent gate line called a previous gate line, which overlaps the pixel electrode 190 via an insulator.

For color display, each pixel uniquely represents one of three colors such as red, green, and blue (i.e., spatial division), or each pixel represents three colors in turn (i.e., time division), such that a spatial or temporal sum of the three colors is recognized as a desired color. The three colors may be primary colors, or other colors not specifically described herein. FIG. 2 shows an example of the spatial division in which each pixel is provided with a color filter 230 representing one of the three colors, i.e., one of red, green, and blue color filters, in an area of the upper panel 200 facing the pixel electrode 190. Alternatively, the color filter 230 is provided on or under the pixel electrode 190 on the lower panel 100.

A pair of polarizers (not shown) polarizing the light emitted from a light source unit (not shown) is attached on the outer surfaces of the panels 100 and 200 of the LC panel assembly 300, respectively. Alternatively, one or more polarizers may be provided.

Referring to FIG. 1 again, the gray voltage generator 800 generates a plurality of gray scale voltages relating to the brightness of the LCD. The gray voltage generator 800 generates two sets of a plurality of gray voltages related to the transmnittance of the pixels, and provides the gray voltages to the data driver 500. The data driver 500 applies the gray voltages, which are selected for each data line D₁-Dₘ, by control of the signal controller 600, to the data line respectively as a data signal. The gray voltages in one set have a positive polarity with respect to the common voltage Vcom, while those in the other set have a negative polarity with respect to the common voltage Vcom.

The gate driver 400 is connected to the gate lines G₁-Gₙ of the LC panel assembly 300, and synthesizes the gate-on voltage Von and the gate-off voltage Voff from an external device to generate gate signals having combinations of the gate-on voltage Von and the gate-off voltage Voff for application to the gate lines G₁-Gₙ. The gate driver 400 is mounted on the LC panel assembly 300, and it may include a plurality of integrated circuit (“IC”) chips.

The data driver 500 is connected to the data lines D₁-Dₘ of the LC panel assembly 300 and applies data voltages, which are selected from the gray voltages supplied from the gray voltage generator 800, to the data lines D₁-Dₘ. The data driver 500 is also mounted on the LC panel assembly 300, and it may also include a plurality of IC chips.

The IC chips of the drivers 400 and 500 may be mounted on flexible printed circuit (“FPC”) films as a tape carrier package (“TCP”), and are attached to the LC panel assembly 300. Alternately, the drivers 400 and 500 may be integrated into the LC panel assembly 300 along with the display signal lines G₁-Gₙ and D₁-Dₘ, and the TFT switching elements Q.

The signal controller 600 controls the gate driver 400 and the data driver 500, and it may be mounted on a printed circuit board (“PCB”).

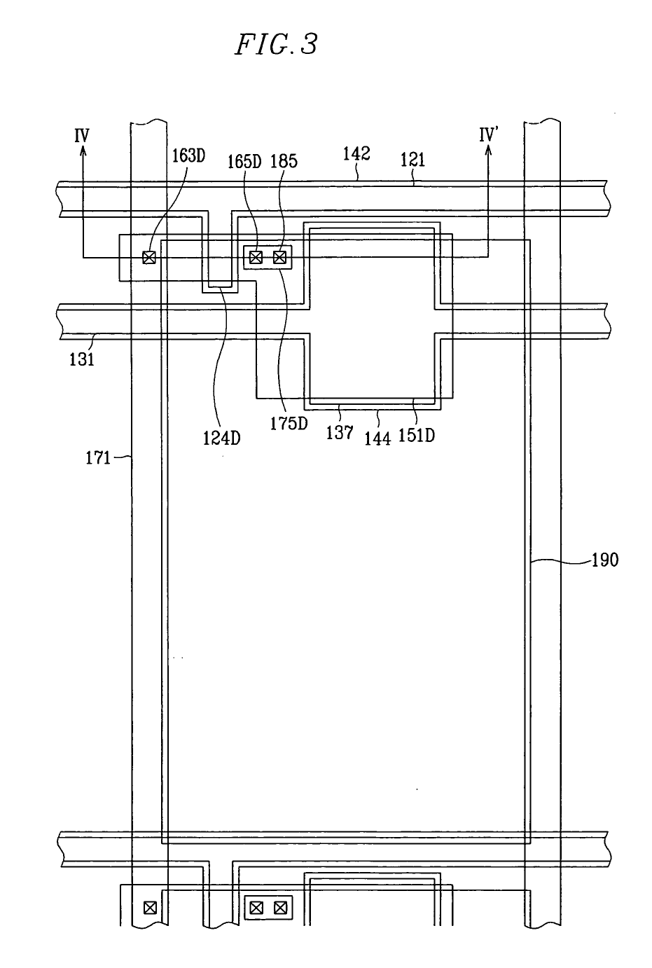

An exemplary embodiment of a TFT array panel for an LCD according to the present invention will now be described in detail with reference to FIGS. 3 to 5 as well as FIGS. 1 and 2.

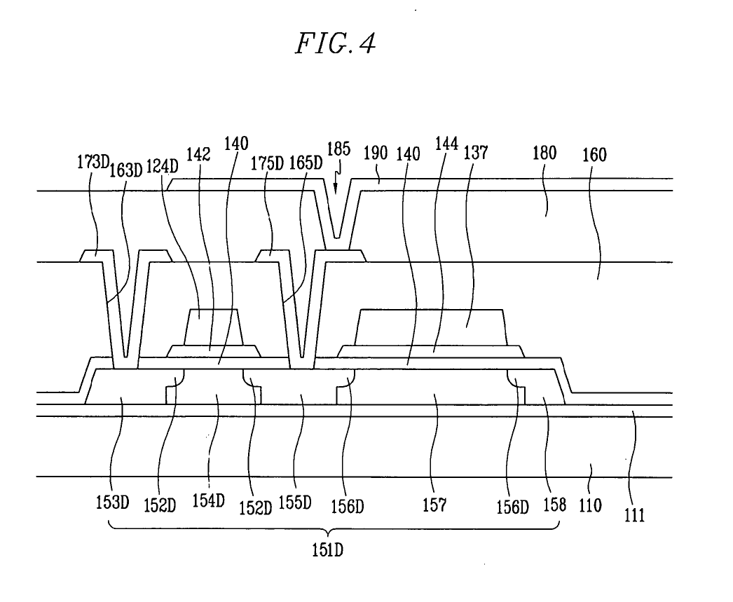

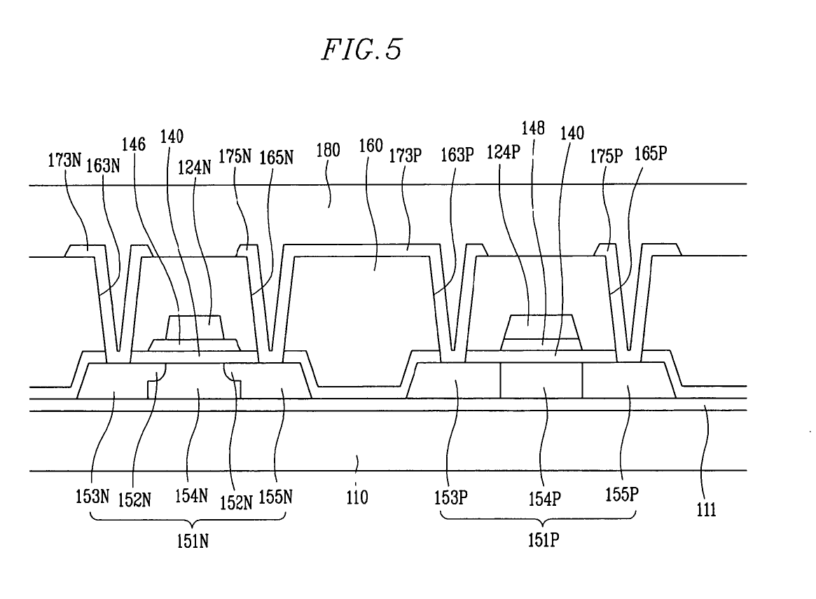

FIG. 3 is a layout view of an exemplary embodiment of the TFT array panel shown in FIGS. 1 and 2 according to the present invention, FIG. 4 is a sectional view of the exemplary display area shown in FIG. 3 taken along line IV-I′, and FIG. 5 is a sectional view of a TFT of the driver shown in FIGS. 1 and 2.

A blocking film 111, exemplararily made of silicon oxide (SiO₂) or silicon nitride (SiNx), is formed on an insulating substrate 110 such as transparent glass, quartz, or sapphire, and other suitable materials would also be within the scope of these embodiments. The blocking film 111 may have a dual-layered structure.

A plurality of semiconductor islands 151D, 151N, and 151P, preferably made of polysilicon, are formed on the blocking film 111. Each of the semiconductor islands 151D, 151N, and 151P includes a plurality of extrinsic regions containing N-type or P-type conductive impurities and at least one intrinsic region containing little of the conductive impurities. It should be understood that an impurity is a substance that is incorporated into a semiconductor material and provides free electrons (N-type impurity) or holes (P-type impurity).

Concerning a semiconductor island 151D for a pixel, the intrinsic regions include a channel region 154D and a storage region 157, and the extrinsic regions are doped with N-type impurities such as phosphorous (P) and arsenic (As), and include a plurality of heavily doped regions such as source and drain regions 153D and 155D separated from each other with respect to the channel region 154D and dummy regions 158. A plurality of lightly doped regions 152D and 156D are disposed between the intrinsic regions 154D and 157 and the heavily doped regions 153D, 155D, and 158.

Regarding a semiconductor island 151N for an N-type TFT, the intrinsic region includes a channel region 154N, and the extrinsic regions are also doped with N-type impurities and include a plurality of heavily doped regions such as source and drain regions 153N and 155N separated from each other with respect to the channel region 154N and a plurality of lightly doped regions 152N disposed between the channel region 154N and the heavily doped regions 153N and 155N.

Concerning a semiconductor island 151P for a P-type TFT, the intrinsic region includes a channel region 154P, and the extrinsic regions are doped with P-type impurities such as boron (B) and gallium (Ga), and include a plurality of heavily doped regions such as source and drain regions 153P and 155P separated from each other with respect to the channel region 154P. In an alternative embodiment, a plurality of lightly doped regions may be disposed between the channel region 154P and the heavily doped regions 153P and 155P.

The lightly doped regions 152D, 152N, and 156D have relatively small thicknesses and lengths compared with the heavily doped regions 153D, 153N, 155D, 155N, and 158, and are disposed close to upper surfaces of the semiconductor islands 151D and 151N. The lightly doped regions 152D/152N disposed between the source region 153D/153N and the channel region 154D/154N and between the drain region 155D/155N and the channel region 154D/154N are referred to as lightly doped drain (“LDD”) regions, and they prevent leakage current of the TFTs. The LDD regions may further prevent a “punch through” phenomenon, where a punch-through voltage may represent junction breakdown. The LDD regions may be substituted with offset regions that contain substantially no impurities.

A gate insulating layer 140 is formed on the semiconductor islands 151D, 151N, and 151P. The gate insulating layer 140 may be made of silicon nitride (SiNx) or silicon oxide (SiO₂).

A plurality of impurity layers 142, 144, 146, and 148, which are heavily doped with N-type impurities, are formed on the gate insulating layer 140 over the semiconductor islands 151D, 151N, and 151P. Each of the impurity layers 142, 146, 148, and 144 respectively overlaps the channel regions 154D, 154N, and 154P, and the storage region 157. The impurity layers 142, 144, and 146 are respectively extended over the lightly doped regions 152D, 156D, and 152N.

A plurality of gate conductors including a plurality of gate lines 121, a plurality of storage electrode lines 131, a plurality of gate electrodes 124N for N-type TFTs, and a plurality of gate electrodes 124P for P-type TFTs are formed on the impurity layers 142, 144, 146, and 148, respectively.

The gate lines 121 for transmitting gate signals extend substantially in a transverse direction and include a plurality of gate electrodes 124D for pixels, where the gate electrodes 124D protrude downwardly to overlap the channel regions 154D of the semiconductor islands 151D. Each gate line 121 may include an expanded end portion having a large area for contact with another layer or an external driving circuit. The gate lines 121 may be directly connected to a gate driving circuit for generating the gate signals, which may be integrated on the insulating substrate 110.

The storage electrode lines 131 are supplied with a predetermined voltage such as a common voltage to form a storage capacitance of the pixels, and include a plurality of storage electrodes 137 protruding upward and downward relative to the storage electrode lines 131, overlapping the storage regions 157 of the semiconductor islands 151D.

The gate lines 121, the storage electrode lines 131, and the gate electrodes 124N are narrower than the impurity layers 142, 144, and 146 by a width of the lightly doped regions 152D, 156D, and 152N, respectively. The gate lines 121, the storage electrode lines 131, and the gate electrodes 124N only overlap the channel regions 154D, the storage regions 157, and the channel regions 154N, respectively, and the gate electrodes 124P for P-type TFTs have substantially the same planar shape as the impurity layer 148.

The gate conductors 121, 131, 124N, and 124P have tapered lateral sides relative to a surface of the substrate 110, and the inclination angles thereof range about 30 to about 80 degrees.

An interlayer insulating layer 160 is formed on the gate conductors 121, 131, 124N, and 124P, as well as on the exposed portions of the gate insulating layer 140. The interlayer insulating layer 160 is preferably made of a photosensitive organic material having a good flatness characteristic, a low dielectric insulating material such as a-Si:C:O and a-Si:O:F formed by plasma enhanced chemical vapor deposition (“PECVD”), or an inorganic material such as silicon nitride and silicon oxide.

The interlayer insulating layer 160 has a plurality of contact holes 163D, 163N, 163P, 165D, 165N, and 165P exposing the source regions 153D, 153N, and 153P and the drain regions 155D, 155N, and 155P, respectively.

A plurality of data conductors including a plurality of data lines 171, a plurality of source drain electrodes 173D and 175D for pixels, a plurality of source and drain electrodes 173N and 175N for N-type TFTs, and a plurality of source and drain electrodes 173P and 175P for P-type TFTs are formed on the interlayer insulating layer 160.

The data lines 171 for transmitting data voltages extend substantially in the longitudinal direction and intersect the gate lines 121. When an adjacent parallel pair of the data lines 171 and an adjacent parallel pair of the gate lines 121 are intersected, a pixel region is defined therein, within the rectangular area formed there between. Each data line 171 includes a plurality of source electrodes 173D for pixels connected to the source regions 153D through the contact holes 163D. Each data line 171 may include an expanded end portion having a large area for contact with another layer or an external driving circuit. The data lines 171 may be directly connected to a data driving circuit for generating the gate signals, which may be integrated on the insulating substrate 110.

The source electrodes 173N and 173P are connected to the source regions 153N and 153P through the contact holes 163N and 163P, respectively.

The drain electrodes 175D/175N/175P are separated from the source electrodes 173D/173N/173P and connected to the drain regions 155D/155N/155P through the contact holes 165D/165N/165P. The drain electrodes 175N for N-type TFTs and the source electrodes 173P for P-type TFTs are connected to each other.

The data conductors 171, 173D, 175D, 173N, 175N, 173P, and 175P are preferably made of refractory metal including chromium Cr, molybdenum Mo, titanium Ti, tantalum Ta, or alloys thereof. They may have a multi-layered structure preferably including a low resistivity film and a good contact film. A good example of the multi-layered structure includes a Mo lower film, an Al middle film, and a Mo upper film as well as the above-described combinations of a Cr lower film and an Al—Nd upper film and an Al lower film and a Mo upper film.

In addition, like the gate conductors 121, 131, 124N, and 124P, the data conductors 171, 173D, 175D, 173N, 175N, 173P, and 175P have tapered lateral sides relative to a surface of the substrate 110, and the inclination angles thereof range about 30 to about 80 degrees.

A passivation layer 180 is formed on the data conductors 171, 173D, 175D, 173N, 175N, 173P, and 175P, and the interlayer insulating layer 160. The passivation layer 180 is also preferably made of a photosensitive organic material having a good flatness characteristic, a low dielectric insulating material such as a-Si:C:O and a-Si:O:F formed by PECVD, or an inorganic material such as silicon nitride and silicon oxide. The passivation layer 180 may have a double-layered structure including a lower inorganic film and an upper organic film.

The passivation layer 180 has a plurality of contact holes 185 exposing the drain electrodes 175D. The passivation layer 180 may further have a plurality of contact holes (not shown) exposing end portions of the data lines 171, and the passivation layer 180 and the interlayer insulating layer 160 may have a plurality of contact holes (not shown) exposing end portions of the gate lines 121.

A plurality of pixel electrodes 190, which are preferably made of at least one of a transparent conductor such as ITO or IZO and an opaque reflective conductor such as Al or Ag, are formed on the passivation layer 180.

The pixel electrodes 190 are physically and electrically connected to the drain electrodes 175D through the contact holes 185 such that the pixel electrodes 190 receive the data voltages from the drain regions 155 via the drain electrodes 175D.

Referring back to FIG. 2, the pixel electrodes 190 supplied with the data voltages generate electric fields in cooperation with the common electrode 270 on the upper panel 200, which determine orientations of liquid crystal molecules in a liquid crystal layer 3 disposed therebetween or cause currents in light emitting members (not shown) disposed therebetween.

As described above, a pixel electrode 190 and a common electrode 270 form a liquid crystal capacitor Clc and a pixel electrode 190, and a drain region 155D connected thereto and a storage electrode line 131 including the storage electrodes 137 form a storage capacitor Cst.

A plurality of contact assistants or connecting members (not shown) may also be formed on the passivation layer 180 such that they are connected to the exposed end portions of the gate lines 121 or the data lines 171.

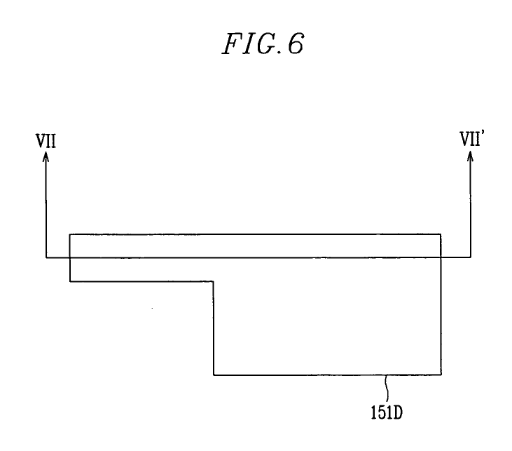

Now, an exemplary embodiment of a method of manufacturing the TFT array panel shown in FIGS. 2 to 5 according to the present invention will be described in detail with reference to FIGS. 6 to 31 as well as FIGS. 3 to 5.

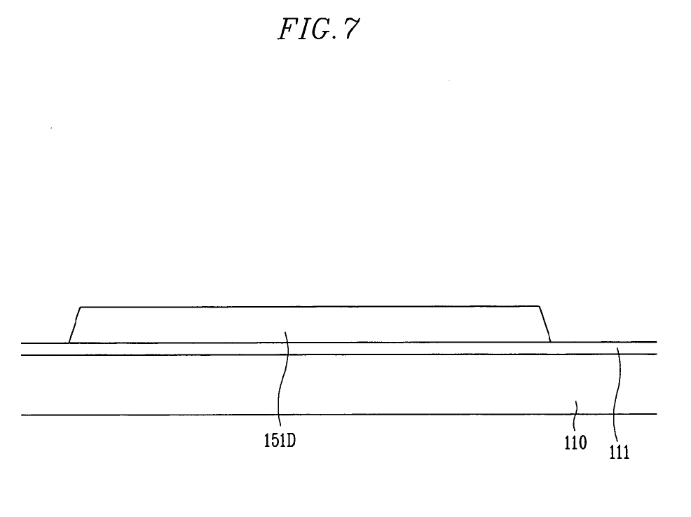

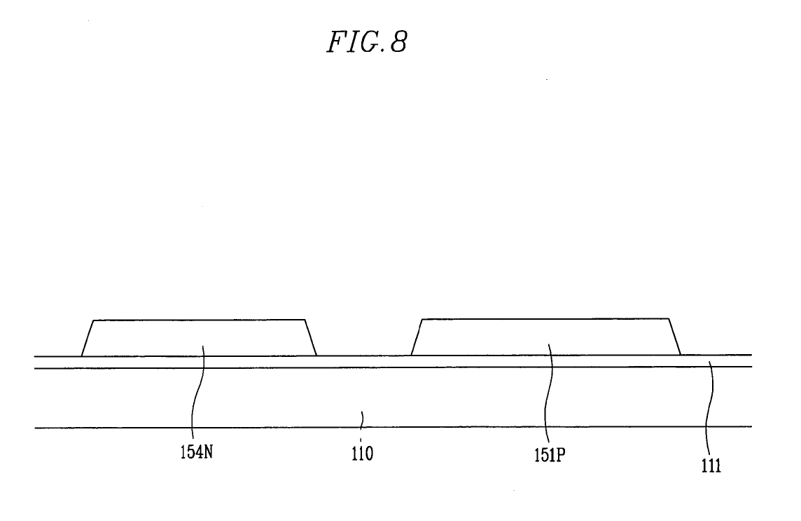

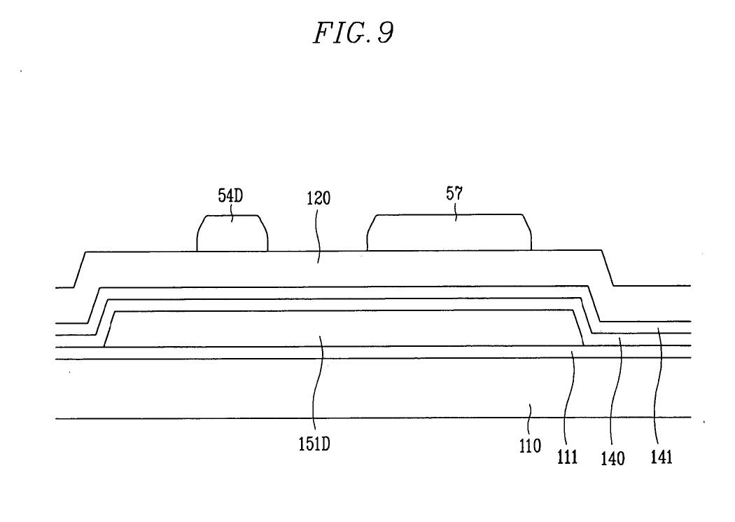

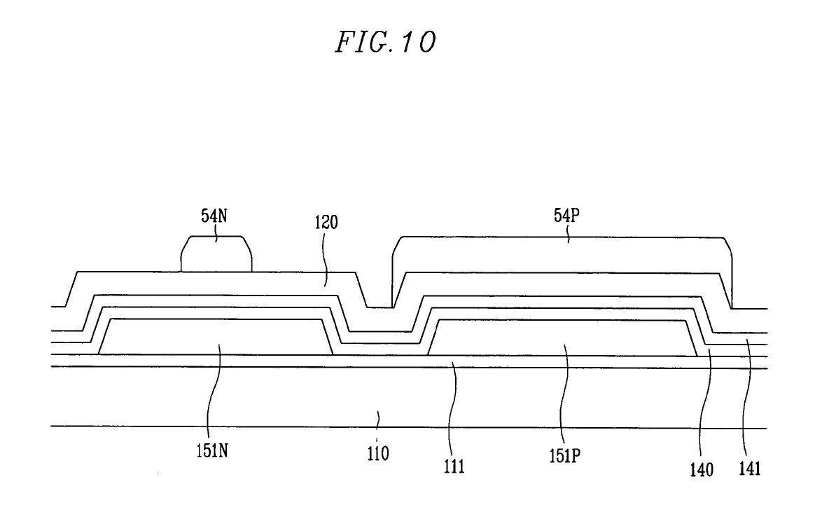

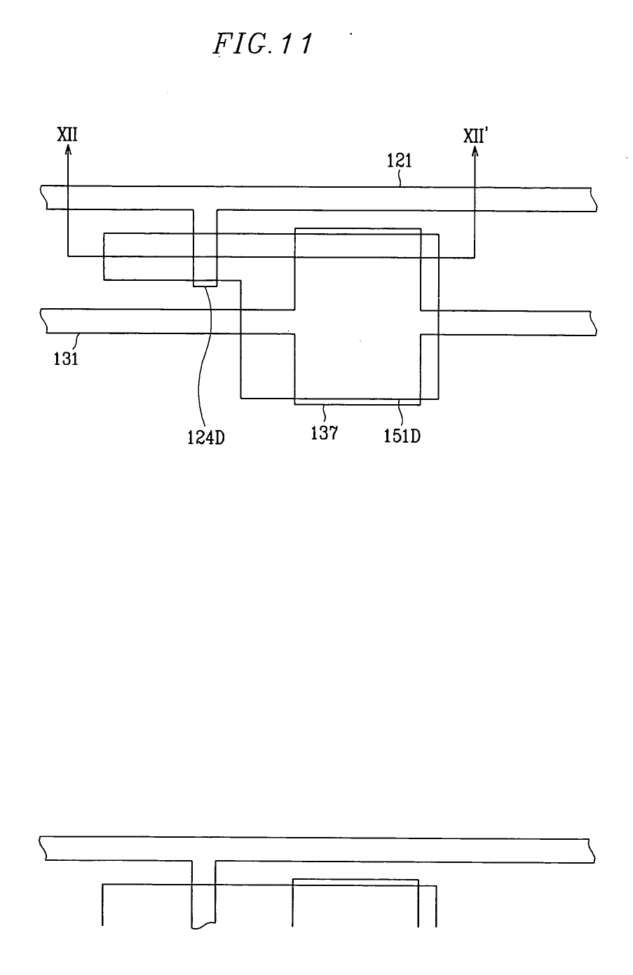

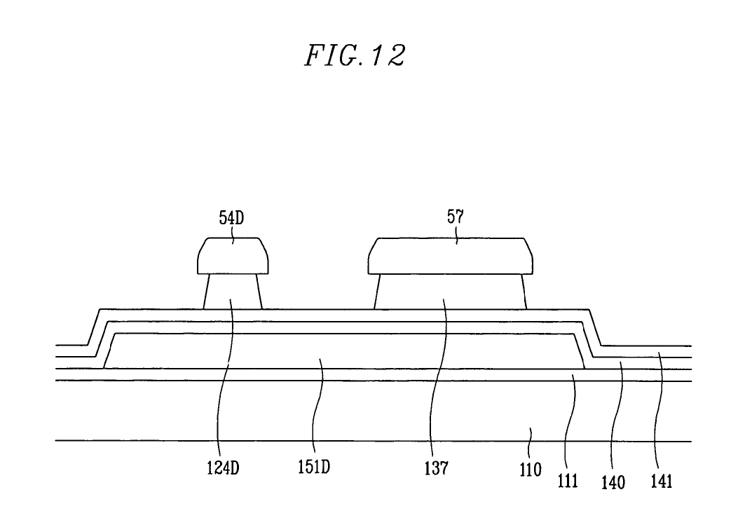

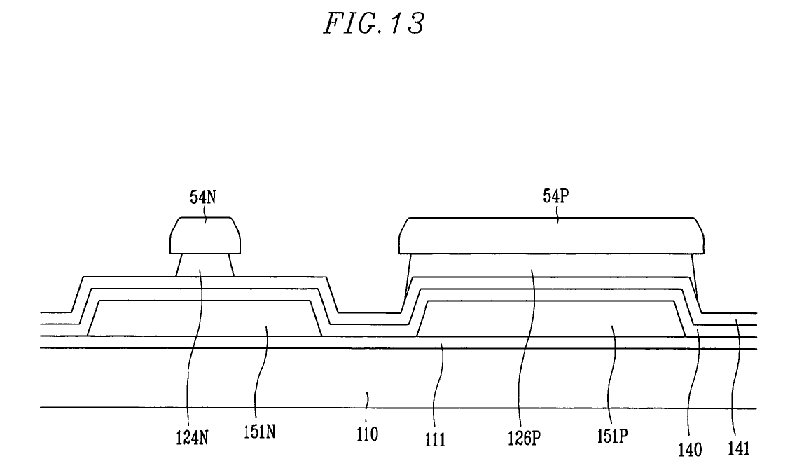

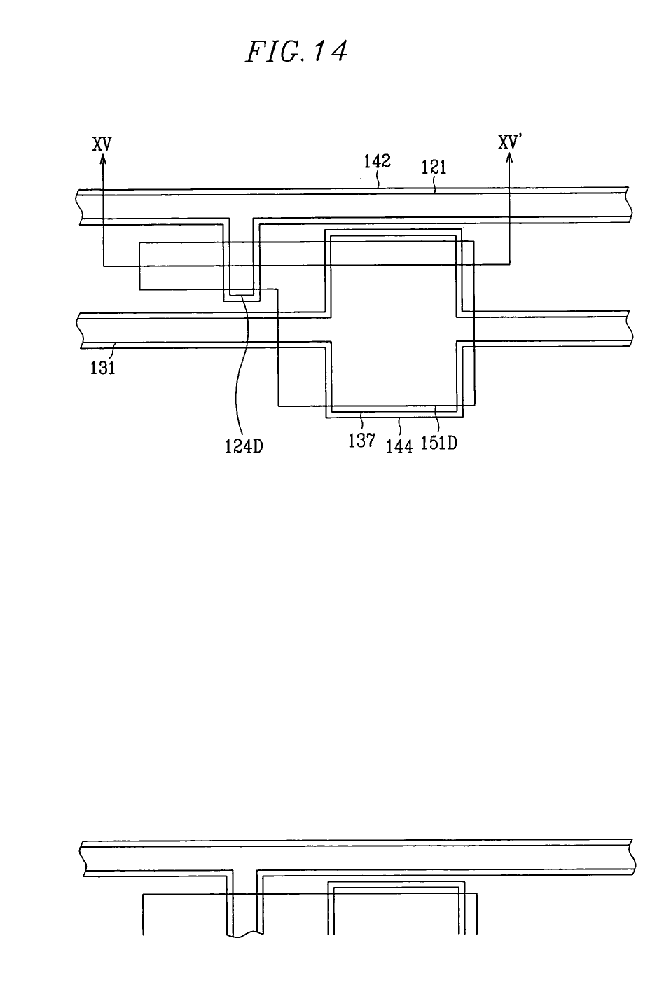

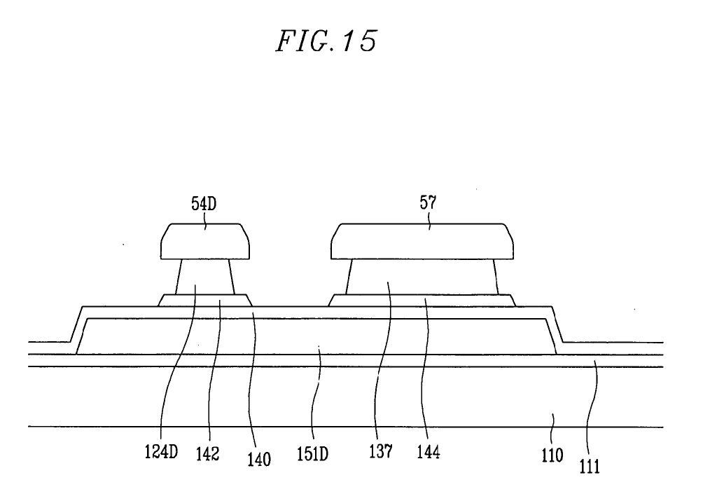

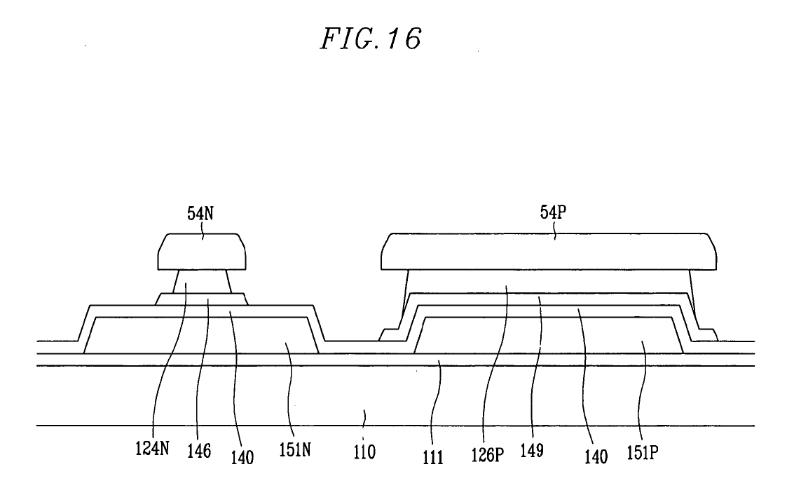

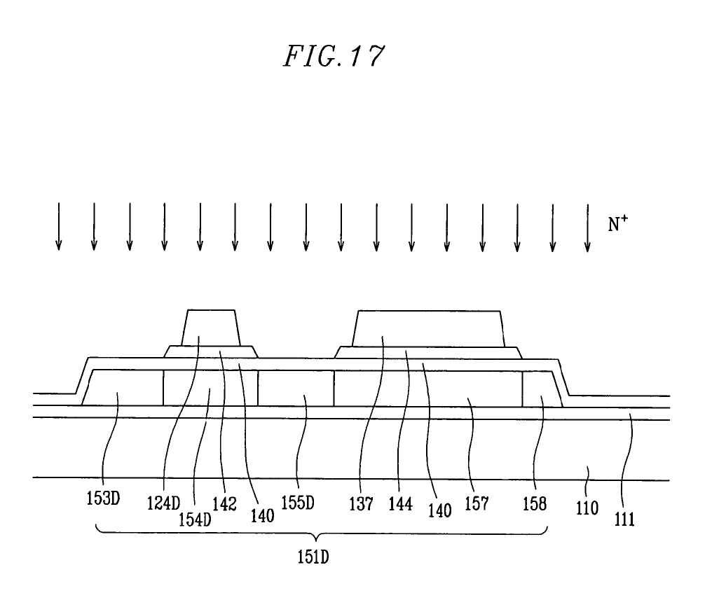

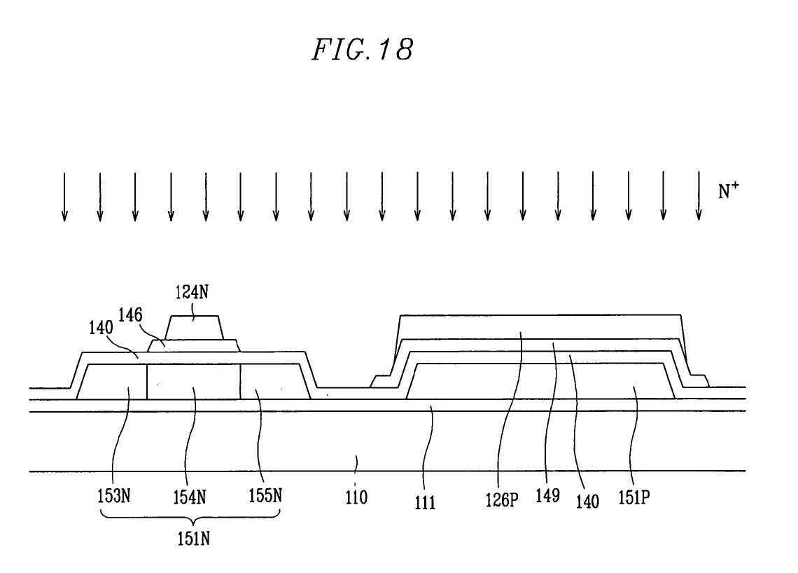

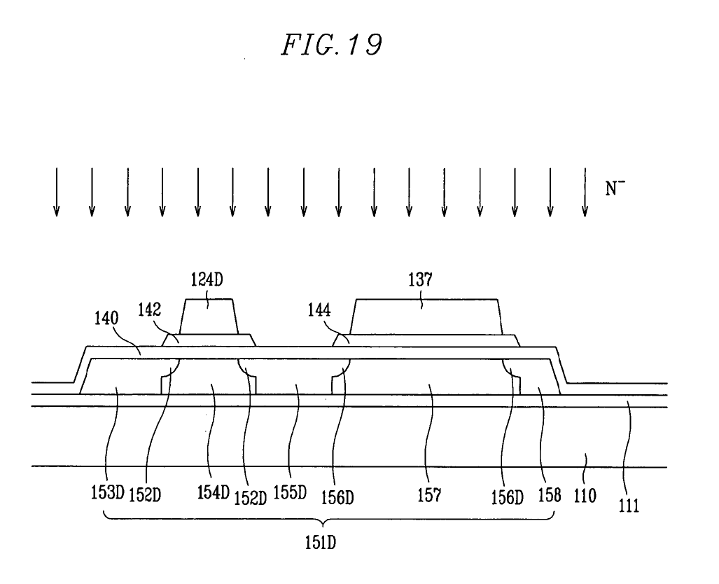

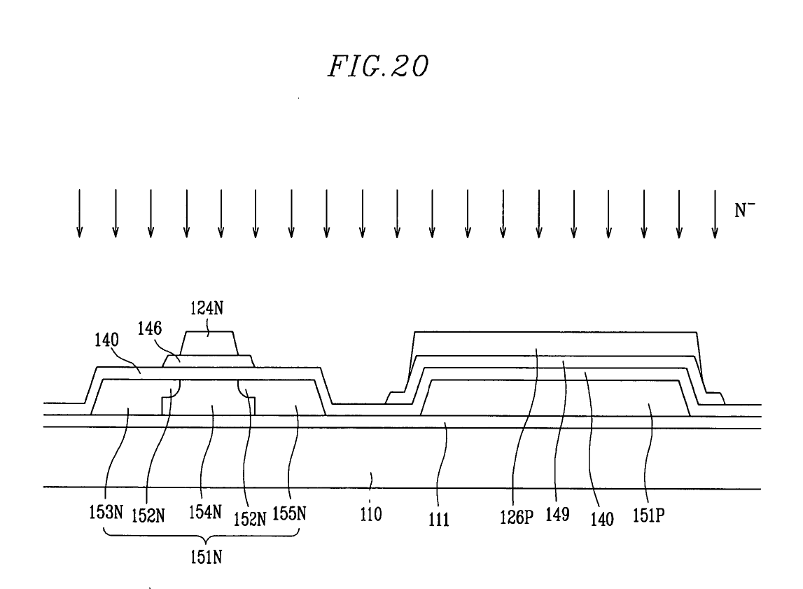

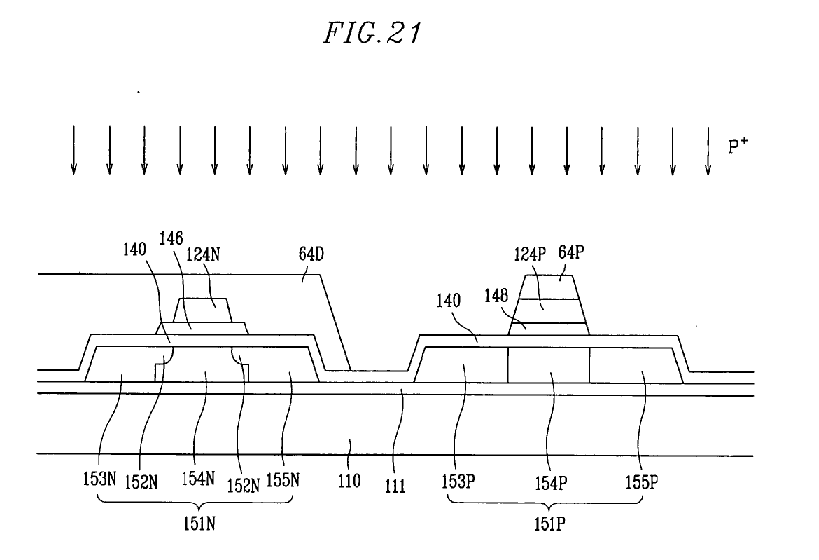

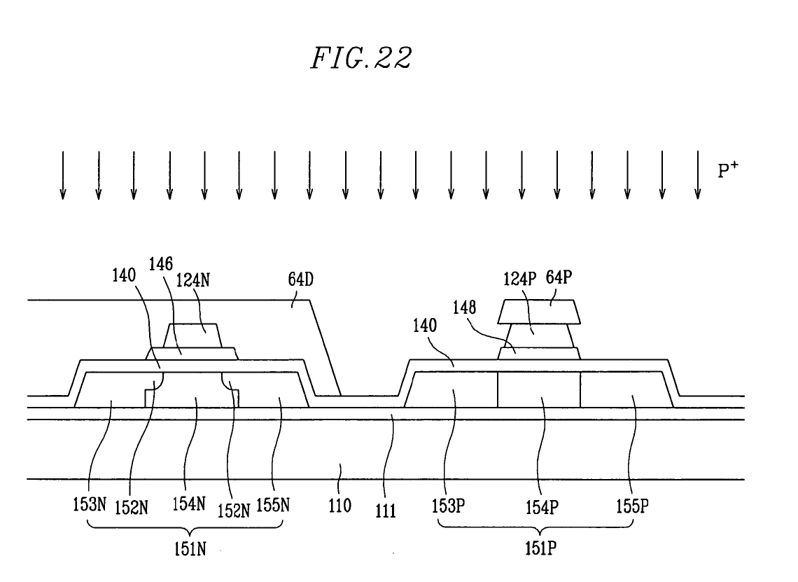

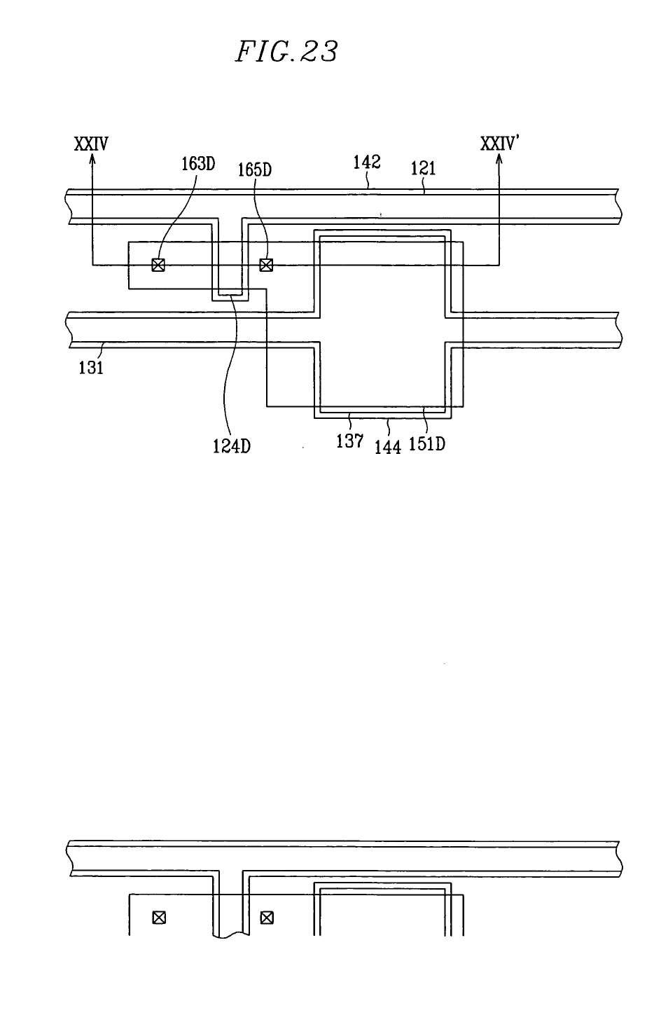

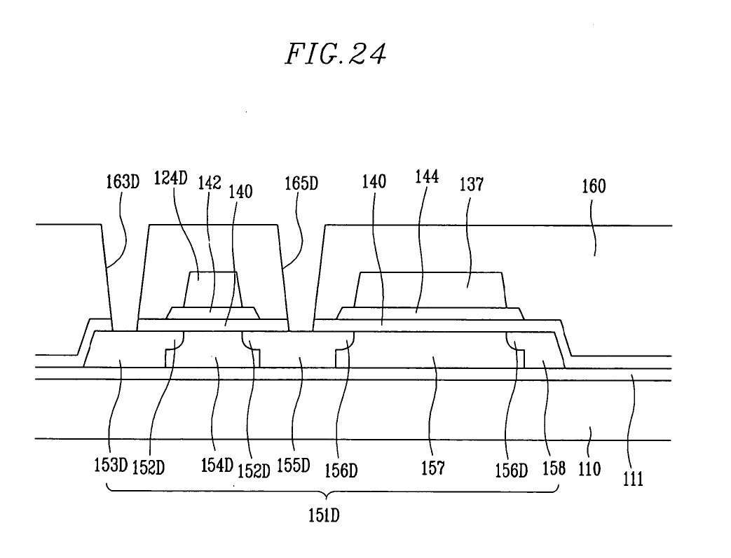

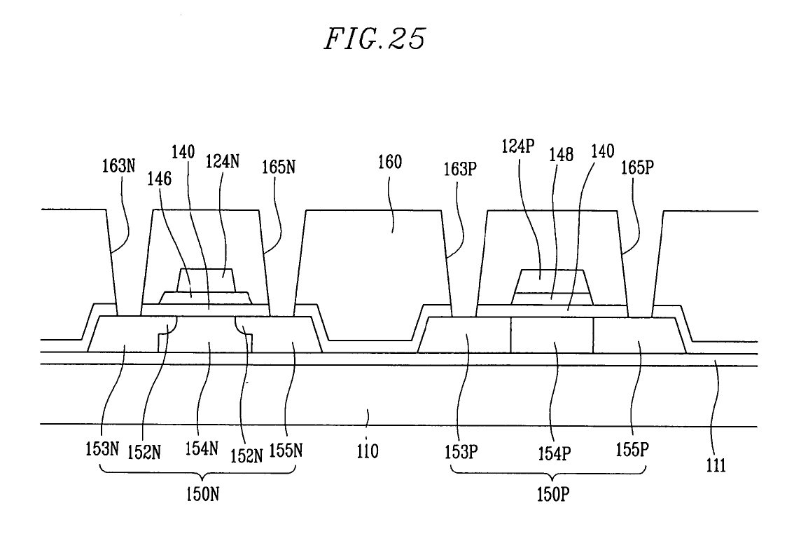

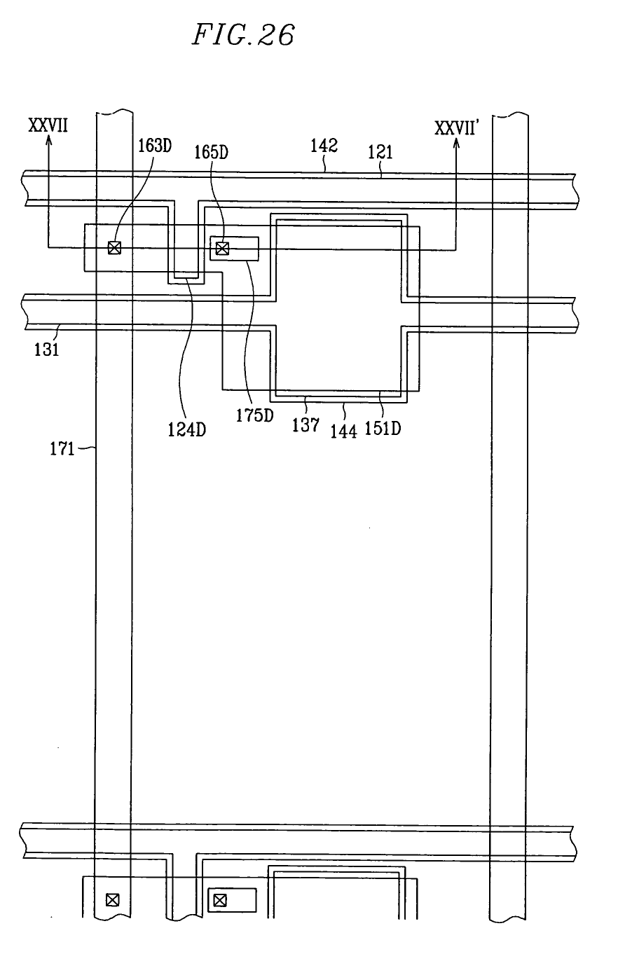

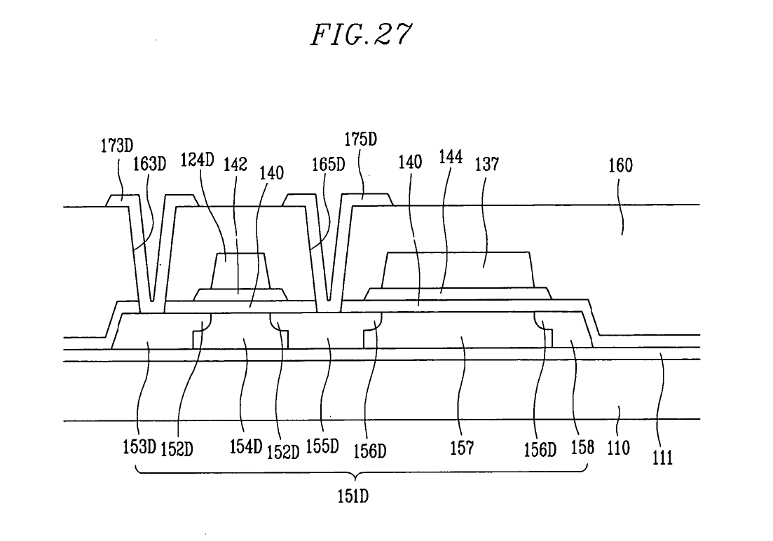

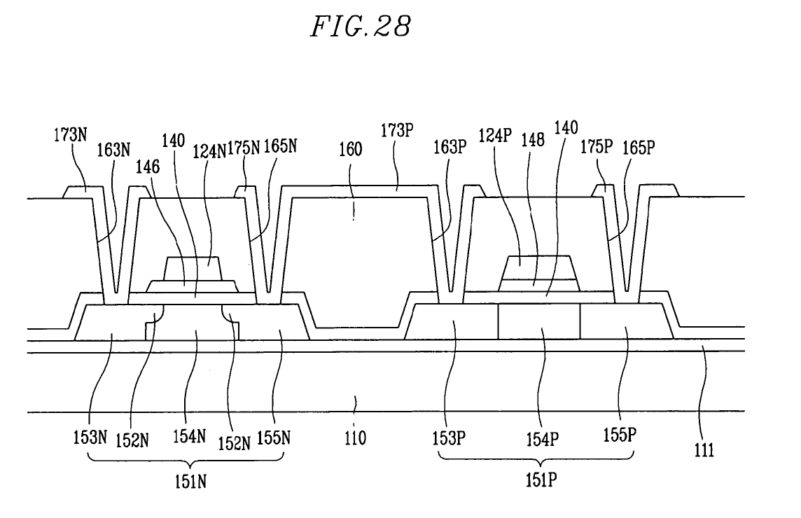

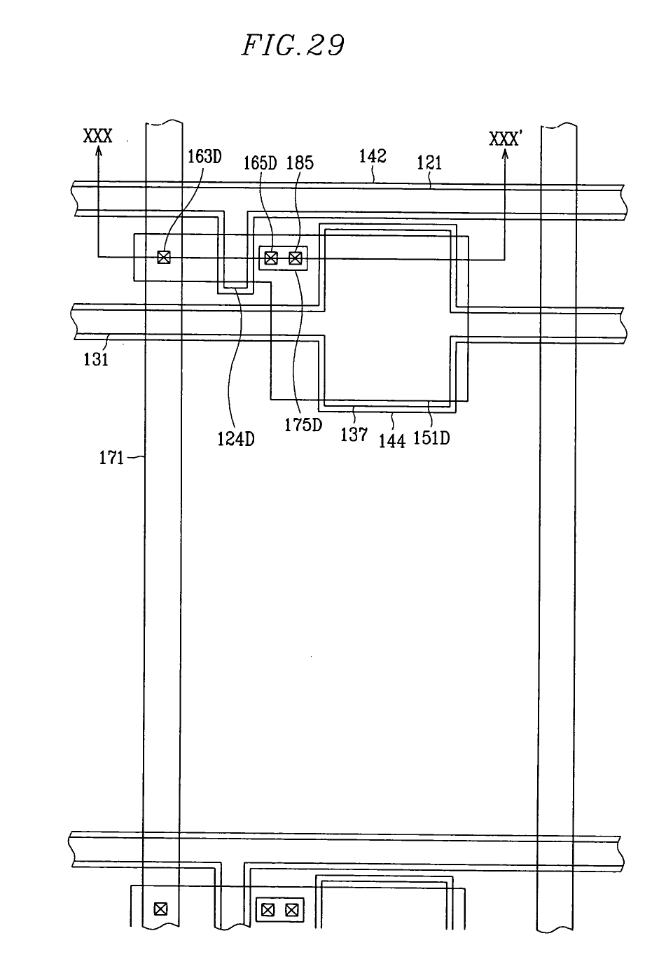

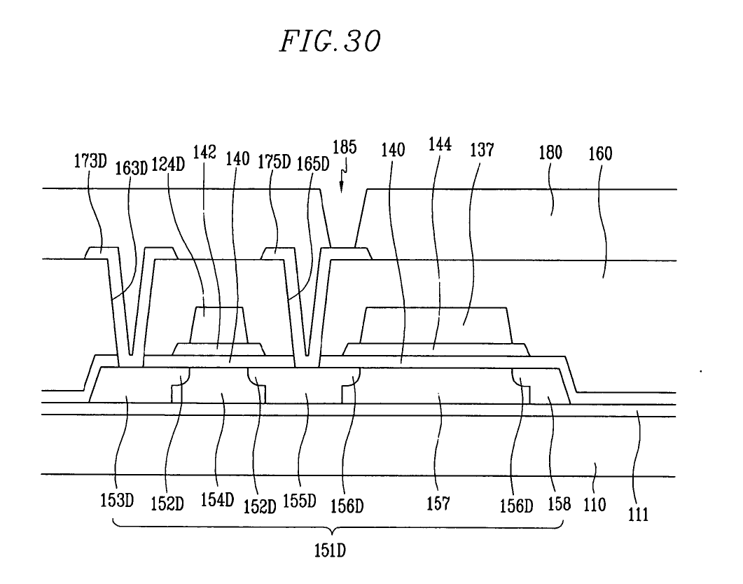

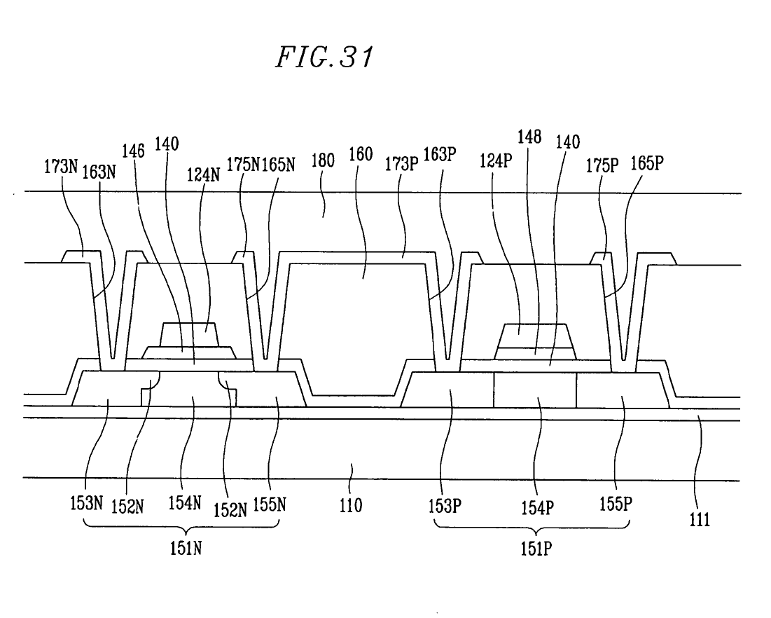

FIG. 6 is a layout view of an exemplary embodiment of the TFT array panel shown in FIGS. 3 and 4 in the first step of a manufacturing method thereof according to the present invention; FIG. 7 is a sectional view of the TFT array panel shown in FIG. 6 taken along line VII-VII′; FIG. 8 is a sectional view of the TFT of the driver shown in FIG. 5 in the step shown in FIGS. 6 and 7; FIG. 9 is a sectional view of the TFT array panel shown in FIG. 6 taken along line VII-VII′, and illustrates the step following the step shown in FIGS. 7 and 8; FIG. 10 is a sectional view of the TFT of the driver in the step shown in FIG. 9; FIG. 11 is a layout view of the TFT array panel in the step following the step shown in FIGS. 9 and 10; FIG. 12 is a sectional view of the TFT array panel shown in FIG. 11 taken along line XII-XII′; FIG. 13 is a sectional view of the TFT of the driver in the step shown in FIGS. 11 and 12; FIG. 14 is a layout view of the TFT array panel in the step following the step shown in FIGS. 11 to 13; FIG. 15 is a sectional view of the TFT array panel shown in FIG. 14 taken along line XV-XV′; FIG. 16 is a sectional view of the TFT of the driver in the step shown in FIGS. 14 and 15; FIG. 17 is a sectional view of the TFT array panel shown in FIG. 14 taken along line XV-XV′, and illustrates the step following the step shown in FIGS. 14 to 16; FIG. 18 is a sectional view of the TFT of the driver in the step shown in FIG. 17; FIG. 19 is a sectional view of the TFT array panel shown in FIG. 14 taken along line XV-XV′, and illustrates the step following the step shown in FIGS. 17 and 18; FIG. 20 is a sectional view of the TFT of the driver in the step shown in FIG. 19; FIG. 21 is a sectional view of the TFT of the driver in the step following step shown in FIG. 20; FIG. 22 is a sectional view of another exemplary embodiment of the TFT of the driver according to the present invention in the step following the step shown in FIG. 20; FIG. 23 is a layout view of the TFT array panel in the step following the step shown in FIG. 20; FIG. 24 is a sectional view of the TFT array panel shown in FIG. 23 taken along line XXIV-XXIV′; FIG. 25 is a sectional view of the TFT of the driver in the step shown in FIGS. 23 and 24; FIG. 26 is a layout view of the TFT array panel in the step following the step shown in FIGS. 22 to 24; FIG. 27 is a sectional view of the TFT array panel shown in FIG. 26 taken along line XXVII-XXVII′; FIG. 28 is a sectional view of the TFT of the driver in the step shown in FIGS. 26 and 27; FIG. 29 is a layout view of the TFT array panel in the step following the step shown in FIGS. 26a to 28; FIG. 30 is a sectional view of the TFT array panel shown in FIG. 29 taken along line XXX-XXX′; and FIG. 31 is a sectional view of the TFT of the driver in the step shown in FIGS. 29 and 30.

Referring to FIGS. 6 to 8, a blocking film 111 is formed on an insulating substrate 110, and a semiconductor layer preferably made of amorphous silicon a-Si is deposited thereon. The semiconductor layer is then crystallized by laser annealing, furnace annealing, or solidification to form a poly crystalline silicon layer. The resultant poly crystalline silicon layer is patterned by lithography and etching to form a plurality of semiconductor islands 151D, 151N, and 151P.

Referring to FIGS. 9 and 10, a gate insulating layer 140 preferably made of silicon oxide or silicon nitride is deposited with the thickness of about 200-500 Å, and an impurity layer 141 which is heavily doped with N-type impurities is deposited in sequence to a thickness of about 500-1000 Å. Then, a gate conductor film 120 is deposited and a photoresist including a plurality of portions 54D, 57, 54N, and 54P are formed on the gate conductor film 120. The portions 54D and 57 are disposed on the semiconductor islands 151D, and the portions 54N and 54P are disposed on the semiconductor islands 151N and 151P, respectively. It should be noted that the portions 54D and 57 overlie only partial sections of the semiconductor island 151D, and portion 54N overlies only a partial section of the semiconductor island 151N, but portion 54P overlies a full width of the semiconductor island 151P. The photoresist portions include a photo-sensitive material that is exposed to a pattern using a lithography process. During developing, exposed portions of resist are removed leaving a positive image of the mask pattern on the surface.

The gate conductor film 120 is preferably made of a low resistivity material including an aluminum Al-containing metal such as Al and an Al alloy (e.g. Al—Nd), a silver Ag-containing metal such as Ag and an Ag alloy, a copper Cu-containing metal such as Cu and a Cu alloy, a molybdenum Mo-containing metal such as Mo and a Mo alloy, chromium Cr, titanium Ti, and tantalum Ta. The gate conductors 120 may have a multi-layered structure including two films having different physical characteristics. If a two film structure is employed, one of the two films is preferably made of a low resistivity metal including an Al-containing metal, an Ag-containing metal, and a Cu-containing metal for reducing signal delay or voltage drop in the gate conductor film 120. The other film is preferably made of a material such as Cr, Mo, a Mo alloy, Ta, or Ti, which have good physical, chemical, and electrical contact characteristics with other materials such as indium tin oxide (ITO) and indium zinc oxide (IZO). Some examples of the combination of the two films that provide an appropriate combination of preferable characteristics include a lower Cr film and an upper Al—Nd alloy film and a lower Al film and an upper Mo film.

Referring to FIGS. 11 to 13, the gate conductor film 120 is patterned by isotropic etching using the photoresist portions 54D, 57, 54N, and 54P as an etch mask to form a plurality of gate conductors that include a plurality of gate lines 121 including gate electrodes 124D, a plurality of storage electrode lines 131 including storage electrodes 137 on the semiconductor islands 151D, a plurality of gate electrodes 124N for N-type TFTs on the semiconductor islands 151N, and a plurality of electrode conductors 126P on the semiconductor islands 151P. The electrode conductors 126P fully cover the semiconductor islands 151P. The isotropic etching makes edges of the gate conductors 121, 131, 124N, and 126P lie within edges of the photoresist portions 54D, 57, 54N, and 54P with a difference of about 0.5-1.0 μm, thereby forming an under-cut structure.

In addition, the lateral sides of the gate conductors 121, 131, 124N, and 124P are inclined relative to a surface of the substrate 110, as previously described.

Referring to FIGS. 14 to 16, the impurity layer 141, such as shown in FIG. 13, is patterned by anisotropic etching using the photoresist portions 54D, 57, 54N, and 54P as an etch mask to form a plurality of impurity layer islands 142, 144, 146, and 149. The anisotropic etching makes edges of the impurity islands 142, 144, 146, and 149 lie away from edges of the gate conductors 121, 131, 124N, and 126P. That is, a width of the impurity islands 142, 144, 146, and 149 is greater than a width of the gate conductors 121, 131, 124N, and 126P.

Referring to FIGS. 17 and 18, the photoresist portions 54D, 57, 54N; and 54P are removed and high-concentration N-type impurities are introduced with a low energy of about 3-40 eV into the semiconductor islands 151D and 151N such as by PECVD or plasma emulsion such that regions of the semiconductor islands 151D, 151N, and 151P disposed under the impurity layer islands 142, 144, 146, and 149 are not doped, and remaining regions of the semiconductor islands 151D and 151N are heavily doped, thereby forming extrinsic source and drain regions 153D, 153N, 155D, and 155N and dummy regions 158 as well as intrinsic channel regions 154D and 154N and storage regions 157. It should be understood that doping is the introduction of dopant into a semiconductor for the purpose of altering its electrical properties, where the dopant is an element introduced into the semiconductor to establish either p-type (acceptors) or n-type (donors) conductivity. The low energy prevents damage due to high voltage for generating high energy to stabilize the characteristics of the TFTs.

Referring to FIGS. 19 and 20, low-concentration N-type impurities are implanted with a high energy into the semiconductor islands 151D and 151N by using scanning equipment or ion beam equipment such that regions of the semiconductor islands 151D, 151N, and 151P disposed under the gate conductors 121, 137, 124N, and 126P are not doped, and remaining regions of the semiconductor islands 151D and 151N are heavily doped to form lightly doped regions 152D, 156D, and 152N at upper side portions of the channel regions 154D and 154N and the storage regions 157.

As described above, the photoresist portions 54D, 57, 54N, and 54P for the gate conductors 121, 131, 124N, and 126P are used as an etch mask to etch the impurity layer islands 142, 144, 146, and 149, and the impurity layer islands 142, 144, 146, and 149 are used as a doping mask to form the heavily doped regions 153D, 153N, 155D, 155N, and 158 and the lightly doped regions 152D, 156D, and 152N. Accordingly, the heavily doped regions 153D, 153N, 155D, 155N, and 158 and the lightly doped regions 152D, 156D, and 152N are formed by using a single lithography step, thereby simplifying the manufacturing method to reduce the manufacturing cost. Also, because the gate electrodes 124D and 124N and the impurity islands 142 and 146 are etched under the same etching conditions, the width of the lightly doped regions 152D and 152N may be uniformly formed, and therefore easily controlled. Also, because the impurity islands 142 and 146 and the gate insulating layer 140 include the same material as silicon, the doping energy for the heavily doped regions 153D, 153N, 155D, 155N, and 158 and the lightly doped regions 152D, 156D, and 152N may also be easily controlled.

Furthermore, the formation of the lightly doped regions 152D, 156D, and 152N may be omitted by forming the impurity islands 142,144, and 146.

Referring to FIG. 21, a photoresist including a plurality of portions 64D and 64P is formed. The portions 64D fully cover the semiconductor islands 151D and 151N, and the portions 64P are disposed on the electrode conductors 126P opposite the semiconductor islands 151P. The electrode conductors 126P, previously shown in FIG. 20, are patterned using the photoresist portions 64P to form a plurality of gate electrodes 124P, and the impurity layer islands 149, also previously shown in FIG. 20, are patterned to expose the gate insulating layer 140 on the portions of the semiconductor islands 151P and to form the impurity layer islands 148, having a reduced width as compared to the impurity layer islands 149. Thereafter, high-concentration P-type impurities are implanted with a low energy of about 3-40 eV into the semiconductor islands 151P by PECVD or plasma emulsion such that regions of the semiconductor islands 151P disposed under the impurity layer islands 148 and the gate electrodes 124P are not doped and remaining regions of the semiconductor islands 151P are heavily doped to form source and drain regions 153P and 155P, as well as intrinsic channel regions 154P.

In another exemplary embodiment according to the present invention, as shown in FIG. 22, the gate electrode 124P is over-etched to form an under-cut structure, thereby forming lightly doped regions between the drain regions 153P and 155P and the channel regions 154P.

Referring to FIGS. 23 to 25, an interlayer insulating layer 160 is deposited and patterned to form a plurality of contact holes 163D, 163N, 163P, 165D, 165N, and 165P exposing the source regions 153D, 153N, and 153P and the drain regions 155D, 155N, and 155P, respectively, along with the gate insulating layer 140.

Referring to FIGS. 26 to 28, a plurality of data conductors including a plurality of data lines 171 having source electrodes 173D for pixels, a plurality of drain electrodes 175D for pixels, a plurality of source and drain electrodes 173N and 175N for N-type TFTs, and a plurality of source and drain electrodes 173P and 175P for P-type TFTs are formed on the interlayer insulating layer 160.

Referring to FIGS. 29 to 31, a passivation layer 180 is deposited and patterned to form a plurality of contact holes 185 exposing the drain electrode 175D for pixels.

Referring to FIGS. 3 to 5, a plurality of pixel electrodes 190 are formed on the passivation layer 180.

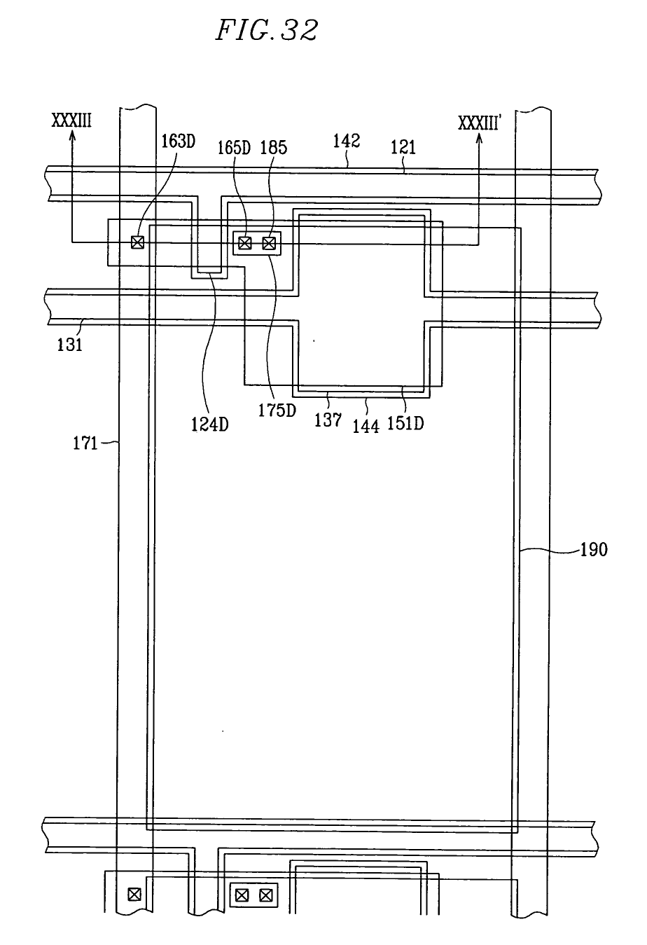

Now, another exemplary embodiment of a TFT array panel for an LCD according to the present invention will be described in detail with reference to FIGS. 32 to 34.

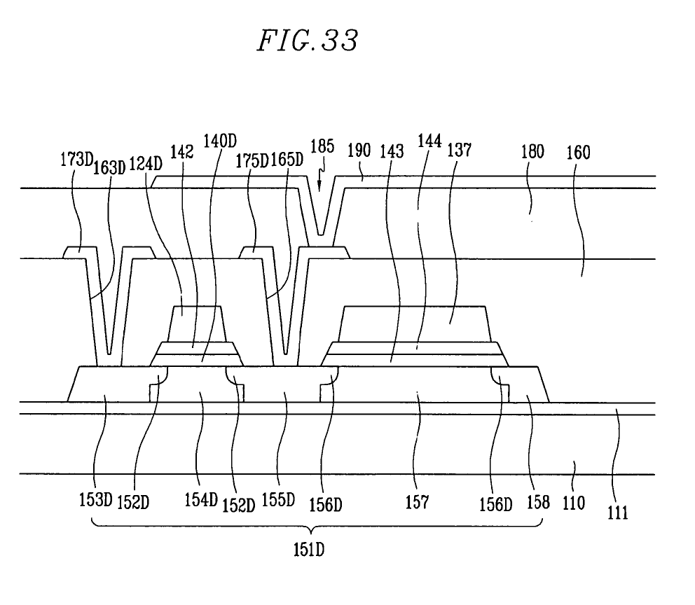

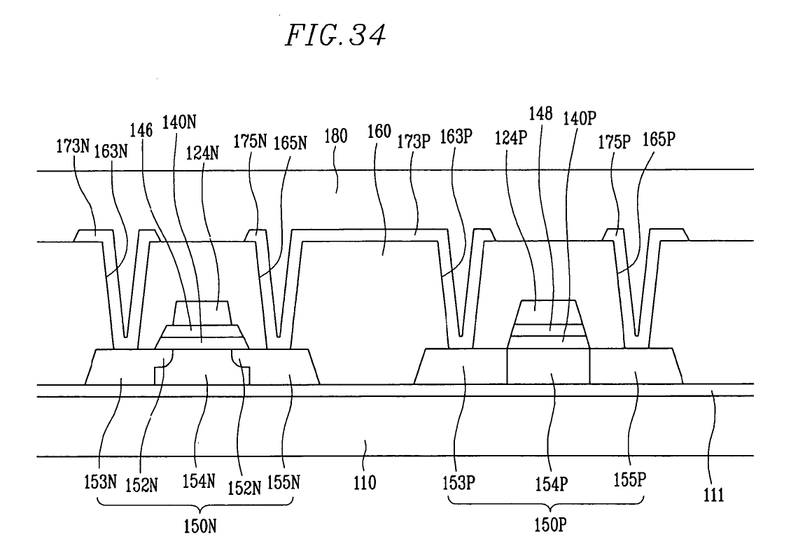

FIG. 32 is a layout view of another exemplary embodiment of a display area of the TFT array panel shown in FIGS. 1 and 2 according to the present invention, FIG. 33 is a sectional view of the exemplary display area shown in FIG. 32 taken along line XXXIII-XXXIII′, and FIG. 34 is a sectional view of a TFT of the driver shown in FIGS. 1 and 2 for the display area of the TFT array panel of FIGS. 32 and 33.

Referring to FIGS. 32 to 34, a layered structure of the TFT array panel according to this embodiment is almost the same as those shown in FIGS. 3 to 5.

That is, a blocking film 111 is formed on an insulating substrate 110, and a plurality of semiconductor islands 151D, 151N, and 151P are formed thereon. The semiconductor islands 151D, 151N, and 151P include channel regions 154D, 154N, and 154P, storage regions 157, source and drain regions 153D, 155D, 153N, 155N, 153P, and 155P, dummy regions 158, and lightly doped regions 152D, 156D, and 152N. Instead of a gate insulating layer 140 covering all of the semiconductor islands 151D, 151N, and 151P and the entire exposed surface of the blocking film 111 as in the prior embodiments, in this embodiment gate insulators 140D, 140N, 140P, and 143 are formed on partial sections of the semiconductor islands 151D, 151N, and 151P, and impurity layer islands 142, 144, 146, and 148 are respectively formed thereon. Similar to the prior embodiments, a plurality of gate conductors including a plurality of gate lines 121, a plurality of storage electrode lines 131, and a plurality of gate electrodes 124N and 124P are formed thereon. An interlayer insulating layer 160 is formed on the gate conductors 121, 131, 124N, and 124P and a plurality of data conductors including a plurality of data lines 171 and a plurality of source and drain electrodes 173N, 173P, 175D, 175N, and 175P are formed on the interlayer insulating layer 160. A passivation layer 180 is formed on the data conductors 171, 175D, 173N, 175N, 173P, and 175P and the interlayer insulating layer 160, and a plurality of pixel electrodes 190 are formed on the passivation layer 180. The interlayer insulating layer 160 has a plurality of contact holes 163D, 163N, 163P, 165D, 165N, and 165P, and the passivation layer 180 has a plurality of contact holes 185.

Thus, different from the TFT array panel shown in FIGS. 3 to 5, gate insulators 140D, 140N, 140P, and 143 have substantially the same planar shape as the impurity layer islands 142, 144, 146, and 148.

Many of the above-described features of the TFT array panel for an LCD shown in FIGS. 3 to 31 may be appropriate to the TFT array panel shown in FIGS. 32 to 34.

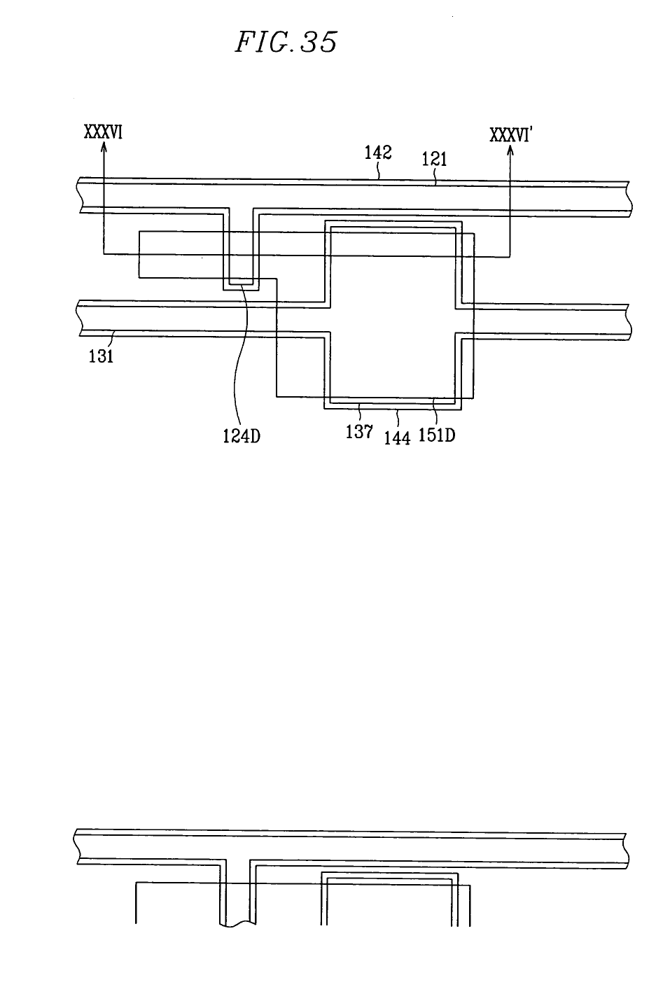

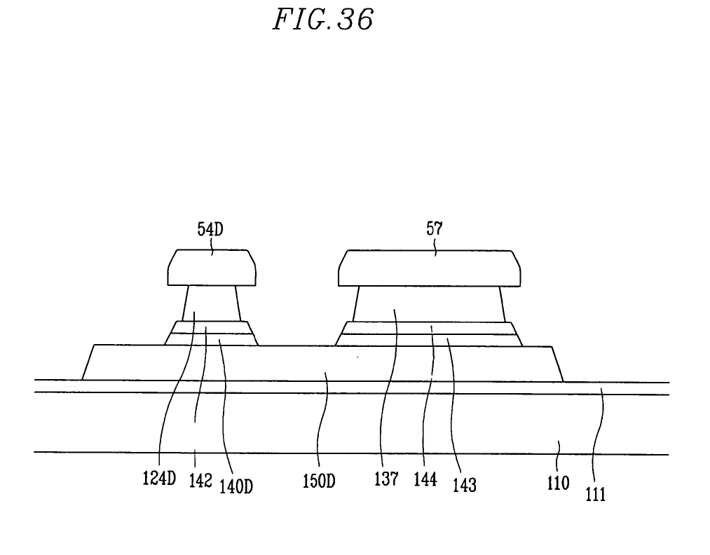

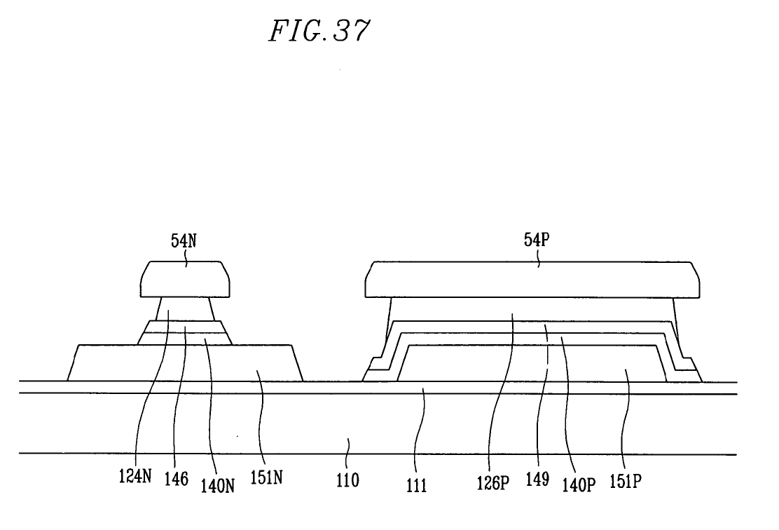

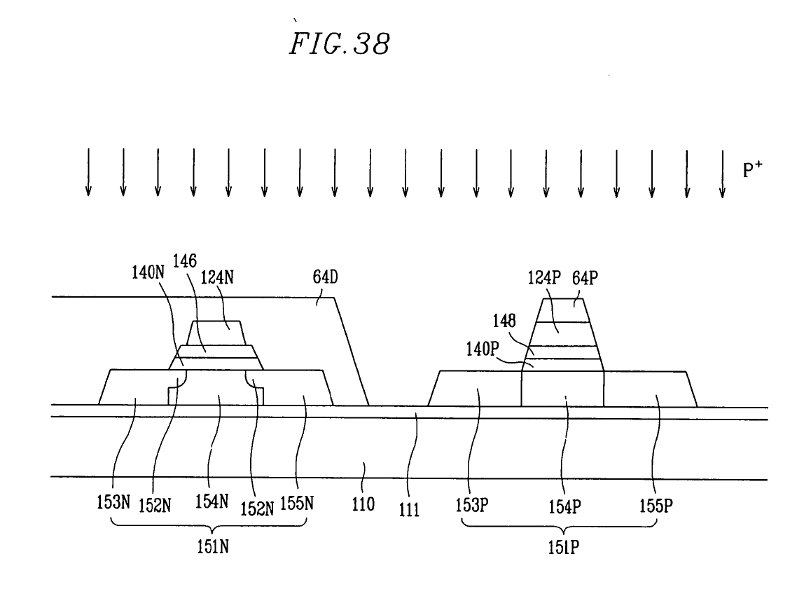

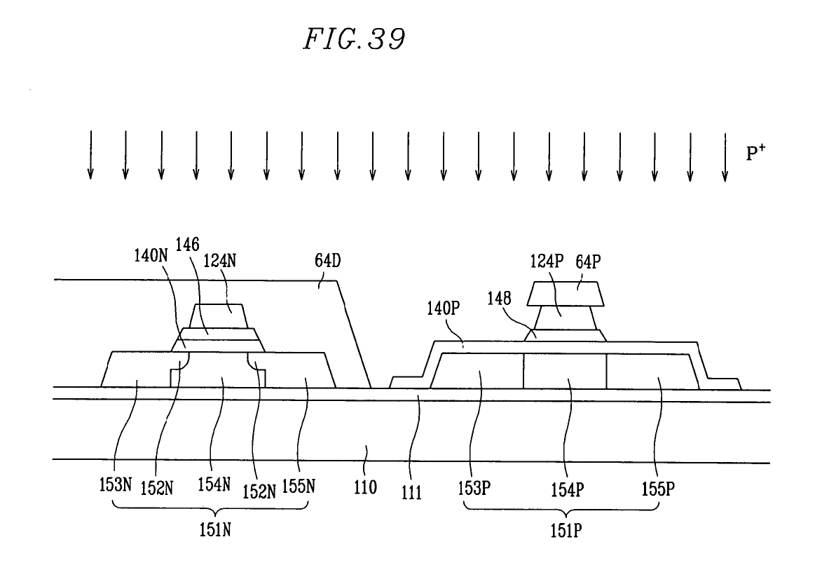

FIG. 35 is a layout view of the TFT array panel in the intermediate step of another exemplary embodiment of a manufacturing method thereof according to the present invention; FIG. 36 is a sectional view of the TFT array panel shown in FIG. 35 taken along line XXXVI-XXXVI′; FIG. 37 is a sectional view of the TFT of the driver in the step shown in FIGS. 35 and 36; FIG. 38 is a sectional view of an exemplary embodiment of the TFT of the driver in the intermediate step of a manufacturing method thereof according to the present invention; and FIG. 39 is a sectional view of another exemplary embodiment of the TFT of the driver in the intermediate step of a manufacturing method thereof according to the present invention.

Referring to FIGS. 35 to 37, a manufacturing method of the TFT array panel according to this embodiment is almost the same as those shown in FIGS. 14-16.

However, as shown in FIGS. 35 to 37, when the impurity layer (not shown) is patterned by anisotropic etching using the photoresist portions 54D, 57, 54N, and 54P as an etch mask to form a plurality of impurity islands 142, 144, 146, and 149, a gate insulating layer, such as gate insulating layer 140, is patterned in sequence to form gate insulators 140D, 140N, 140P, and 143. Thus, the resultant gate insulators 140D, 140N, 140P, and 143 are substantially the same as the gate insulators 140D, 140N, 140P, and 143 formed in FIGS. 32-34.

In this embodiment, referring to FIG. 38, a photoresist including a plurality of portions 64D and 64P is formed. The portions 64D fully cover the semiconductor islands 151D and 151N, and the portions 64P are disposed on the electrode conductors 126P opposite the semiconductor islands 151P. The electrode conductors 126P are patterned using the photoresist portions 64P to form a plurality of gate electrodes 124P and the impurity layer islands 148 are patterned to expose portions of the semiconductor islands 151P. Thereafter, high-concentration P-type impurities are implanted as in the former embodiment.

In another embodiment according to the present invention, as shown in FIG. 39, the gate electrode 124P is over-etched to form an under-cut structure to form lightly doped regions between the source and drain regions 153P and 155P and the channel regions 154P. At this time, the impurity layer islands 148 may have the same planer shape as the photoresist portions 64P, and the gate insulator 140P may be not etched.

As described above, off-current of the TFT may be reduced by adding the doped impurity layer under the gate electrode, and the reliability of the TFT may be enhanced by overlapping the doped impurity layer and the lightly doped regions.

Furthermore, the heavily doped regions and the lightly doped regions are formed by using a single lithography step, thereby simplifying the manufacturing method to reduce the manufacturing cost.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A thin film transistor array panel comprising:
a substrate having a display area and a driver;
a polysilicon layer formed on the substrate, the polysilicon layer including a channel region, source and drain regions, and lightly doped regions disposed between the channel region and the source and the drain regions, the lightly doped regions having an impurity concentration lower than an impurity concentration of the source and the drain regions;
a gate insulating layer formed on the polysilicon layer;
an impurity layer formed on the gate insulating layer and overlapping the channel region of the polysilicon layer, the impurity layer doped with impurities;
a gate electrode formed on the impurity layer;
an interlayer insulating layer covering the gate electrode and having first and second contact holes respectively exposing the source and the drain regions; and
source and drain electrodes respectively connected to the source and the drain regions via the first and the second contact holes.

2. The thin film transistor array panel of claim 1, wherein the polysilicon layer is disposed in the display area.

3. The thin film transistor array panel of claim 1, further comprising:
a gate line connected to the gate electrode;
a data line connected to the source electrode and crossing over the gate line; and
a pixel electrode connected to the drain electrode.

4. The thin film transistor array panel of claim 3, further comprising a passivation layer disposed between the pixel electrode and the drain electrode.

5. The thin film transistor array panel of claim 1, wherein the polysilicon layer is disposed in the driver.

6. The thin film transistor array panel of claim 1, wherein the polysilicon layer includes a first and a second polysilicon layer respectively disposed in the display area and the driver and respectively doped with first and second conductivity impurities.

7. The thin film transistor array panel of claim 6, wherein the first conductivity impurities are N-type impurities and the second conductivity impurities are P-type impurities.

8. The thin film transistor array panel of claim 6, wherein the impurity layer includes first and second impurity layers doped with the first conductivity impurities and respectively disposed on the first and the second polysilicon layers.

9. The thin film transistor array panel of claim 8, wherein the first conductivity impurities are N-type impurities and the second conductivity impurities are P-type impurities.

10. The thin film transistor array panel of claim 8, wherein the lightly doped regions are respectively disposed in the first and the second polysilicon layers and are respectively doped with the first and second conductivity impurities.

11. The thin film transistor array panel of claim 8, wherein the lightly doped regions are only disposed in the first polysilicon layer.

12. The thin film transistor array panel of claim 1, wherein the impurity layer overlaps the lightly doped regions.

13. The thin film transistor array panel of claim 1, wherein the impurity layer does not overlap the source and drain regions.

14. The thin film transistor array panel of claim 1, wherein the impurity layer and the gate insulating layer have a substantially same planar shape.

15. The thin film transistor array panel of claim 14, wherein the gate insulating layer overlaps the channel region and does not overlap the source and drain regions.

16. The thin film transistor array panel of claim 1, wherein the polysilicon layer further includes a storage region spaced from the channel region by the drain region, the impurity layer further comprising a first impurity layer overlapping the channel region and a second impurity layer overlapping the storage region.

17. A method of manufacturing a thin film transistor array panel, comprising:
forming a polysilicon layer on a substrate;
depositing a gate insulating layer on the substrate;
depositing a doped silicon layer on the gate insulating layer;
depositing a conductive film on the doped silicon layer;
forming a photoresist relative to the conductive film;
patterning the conductive film by isotropic etching using the photoresist as an etch mask to form a gate electrode;
patterning the doped silicon layer by anisotropic etching using the photoresist as an etch mask to form an impurity layer;
forming source and drain regions having a first impurity concentration by introducing impurities into the polysilicon layer using the impurity layer as a mask;
forming lightly doped regions having a second impurity concentration lower than the first impurity concentration by introducing impurities into the polysilicon member using the gate electrode as a mask;
forming an interlayer insulating layer covering the gate electrode having contact holes respectively exposing the source and the drain regions; and
forming source and drain electrodes on the interlayer insulating layer, the source and drain electrodes respectively connected to the source and the drain regions via the contact holes.

18. The method of claim 17, further comprising:
forming a pixel electrode connected to the drain electrode.

19. The method of claim 17, wherein introducing impurities for forming source and drain regions is performed by plasma enhanced chemical vapor deposition or plasma emulsion.

20. The method of claim 17, further comprising etching the gate insulating layer when patterning the doped silicon layer.

21. A thin film transistor array panel comprising:
an insulating layer;
a gate conductor transmitting gate signals; and,
an impurity layer doped with impurities and interposed between the insulating layer and the gate conductor.

22. The thin film transistor array panel of claim 21, further comprising a semiconductor layer having a source region, a drain region, and a channel region disposed between the source region and the drain region, wherein the insulating layer is disposed on the semiconductor layer, and the impurity layer overlaps the channel region and does not overlap the source and drain regions.

23. The thin film transistor array panel of claim 22, further comprising a first lightly doped region between the source region and the channel region and a second lightly doped region between the channel region and the drain region, wherein the impurity layer overlaps the first and second lightly doped regions.

24. The thin film transistor array panel of claim 21, wherein the impurity layer is doped with N-type conductive impurities.
